(19) United States
(12) Patent Application Publication
(10) Pub. No.: US 2025/0150036 A1
(43) Pub. Date: May 8, 2025

(54) BIAS CIRCUIT FOR POWER AMPLIFIER

(71) Applicant: Qorvo US, Inc., Greensboro, NC (US)

(72) Inventors: Baker Scott, San Jose, CA (US); Stephen James Franck, Felton, CA (US); George Maxim, Saratoga, CA (US); Sudipta Saha, San Jose, CA (US)

(21) Appl. No.: 18/832,058

(22) PCT Filed: Feb. 2, 2023
(86) PCT No.: PCT/US2023/061804

§ 371 Date: Jul. 22, 2024

Related U.S. Application Data
(60) Provisional application No. 63/306,676, filed on Feb. 4, 2022.
(60) Provisional application No. 63/267,549, filed on Feb. 4, 2022.
(60) Provisional application No. 63/267,553, filed on Feb. 4, 2022.
(60) Provisional application No. 63/267,633, filed on Feb. 7, 2022.
(60) Provisional application No. 63/307,280, filed on Feb. 7, 2022.

(51) Int. Cl. H03F 1/02; H03F 1/32; H03F 1/52; H03F 3/213

(52) U.S. Cl. CPC H03F 1/0227; H03F 1/3241; H03F 1/523; H03F 3/213; H03F 2200/426; H03F 2200/435; H03F 2200/451; H03F 2200/511

(57) ABSTRACT

A bias circuit (3300) for a power amplifier (3310) is disclosed. The bias circuit (3300) may select between different power sources based on a power need for the power amplifier (3310). As voltage levels between the different power sources may differ at the moment of transition, additional circuitry is provided to smooth the transition between the differing power levels. Further, the bias circuit (3300) may provide bias signals to multiple stacked transistors in the power amplifier (3310) in such a manner so as to avoid collapsing any of the transistors. One such approach is a piecewise linear bias signal. Still further, the bias circuit (3300) may interoperate with predistortion circuitry to assist in linear operation of the power amplifier (3310). Still further, the bias circuit (3300) may interoperate with protection circuitry to prevent over current, over voltage, or over power conditions that may damage the power amplifier (3310).

### PRIORITY CLAIMS

The present application claims priority to U.S. Provisional Patent Application Ser. No. 63/267,633 filed on Feb. 7, 2022 and entitled “BIAS CIRCUIT FOR POWER AMPLIFIER,” the contents of which is incorporated herein by reference in its entirety.

The present application also claims priority to U.S. Provisional Patent Application Ser. No. 63/267,549 filed on Feb. 4, 2022 and entitled “POWER AMPLIFIER WITH ANALOG PREDISTORTION,” the contents of which is incorporated herein by reference in its entirety.

The present application also claims priority to U.S. Provisional Patent Application Ser. No. 63/267,553 filed on Feb. 4, 2022 and entitled “POWER AMPLIFIER WITH ANALOG PREDISTORTION,” the contents of which is incorporated herein by reference in its entirety.

The present application also claims priority to U.S. Provisional Patent Application Ser. No. 63/306,676 filed on Feb. 4, 2022 and entitled “CASCODE POWER AMPLIFICATION CIRCUITS, INCLUDING PROTECTION CIRCUITS,” the contents of which is incorporated herein by reference in its entirety.

The present application also claims priority to U.S. Provisional Patent Application Ser. No. 63/307,280 filed on Feb. 7, 2022 and entitled “CASCODE POWER AMPLIFICATION CIRCUITS INCLUDING VOLTAGE PROTECTION CIRCUITS,” the contents of which is incorporated herein by reference in its entirety.

### BACKGROUND

### I. Field of the Disclosure

The technology of the disclosure relates generally to power amplifiers and, more particularly, to bias circuits used to manage power amplifiers.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to increase bandwidth available for communication. Responsive to such pressure, newer wireless communication standards such as the Fifth Generation-New Radio (5G-NR) have changed the operating frequency into the gigahertz range, which in turn requires operation by transmission chains within the mobile communication device across correspondingly wide modulation bandwidths. Having large bandwidth requirements in the transmission chain places a burden on the elements of the transmission chain and particularly the power amplifiers within the transmission chain to operate linearly over the large bandwidth. This burden provides opportunities for innovation.

### SUMMARY

Aspects disclosed herein include bias circuits for power amplifiers. In an exemplary aspect, a bias circuit may select between different power sources based on a power need for the power amplifier. As voltage levels between the different power sources may differ at the moment of transition, additional circuitry is provided to smooth the transition between the differing power levels. Further, the bias circuit may provide bias signals to multiple stacked transistors in a power amplifier in such a manner so as to avoid collapsing any of the transistors. One such approach is a piecewise linear bias signal. Still further, the bias circuit may interoperate with predistortion circuitry to assist in linear operation of the power amplifier. Still further, the bias circuit may interoperate with protection circuitry to prevent over current, over voltage, or over power conditions that may damage the power amplifier. As a nuance, the bias circuit may balance the demands of linear operation against the need to protect the power amplifier. Such a bias circuit that interoperates effectively with protection and linearization circuitry while providing smooth bias signals to the power amplifier may improve overall efficiency of the power amplifier and assist in meeting wireless protocol requirements.

In this regard, in one aspect, a transmission chain is disclosed. The transmission chain comprises a power amplifier stage. The transmission chain also comprises a bias circuit coupled to the power amplifier stage. The bias circuit comprises a bias signal output coupled to the power amplifier stage and configured to provide at least one bias signal to the power amplifier stage. The bias circuit also comprises a first power supply input configured to be coupled to a first power supply. The bias circuit also comprises a second power supply input configured to be coupled to a second power supply. The bias circuit also comprises a switching circuit selectively switching between the first power supply input and the second power supply input. The bias circuit also comprises a float circuit configured to smooth voltage levels when the switching circuit switches between the first power supply input and the second power supply input.

In another aspect, a transmission chain is disclosed. The transmission chain comprises a power amplifier stage. The transmission chain also comprises a bias circuit coupled to the power amplifier stage. The bias circuit comprises a bias signal output coupled to the power amplifier stage and configured to provide at least one bias signal to the power amplifier stage. The bias circuit also comprises an over power protection signal input configured to receive a signal that causes the bias circuit to debias the power amplifier stage. The bias circuit also comprises a predistortion signal input configured to cause the bias circuit to apply a predistortion bias to the power amplifier stage. The bias circuit is configured to disable the predistortion bias when the signal indicates an over power condition is occurring.

### BRIEF DESCRIPTION OF THE DRAWINGS

FIG. 1 is a schematic diagram of a cascode transistor amplifier;

FIG. 2 is a schematic diagram of a power amplification circuit including an amplifier circuit, a protection circuit, and a bias circuit coupled to the power amplification circuit;

FIG. 3 is a schematic diagram of the cascode transistor amplifier in FIG. 1 and a first example of a stress control circuit;

FIG. 4A is a graph of output voltages of signals on an output node of the cascode transistor amplifier of FIG. 1;

FIG. 4B is a graph of a capacitance of a variable capacitor in the stress control circuit of FIG. 3 in response to the output voltages in FIG. 4A;

FIG. 5 is a schematic diagram of the cascode transistor amplifier in FIG. 1 with a second example of the stress control circuit;

FIG. 6 is a schematic diagram of the power amplification circuit of FIG. 2 and the stress control circuit as shown in FIG. 3;

FIG. 7 is a schematic diagram of a two-stage power amplification circuit, including the power amplification circuit of FIG. 6 as a first stage;

FIG. 8 is a block diagram of a transceiver having an exemplary transmission chain which may benefit from the present disclosure;

FIG. 9 is a phase versus power graph showing how phase may distort as power is increased in the transmission chain;

FIG. 10 is a block diagram of an exemplary transmission chain having an analog predistortion (APD) circuit used to offset phase distortion in the transmission chain;

FIG. 11 is a block diagram expanding the power amplifier of FIG. 10, showing where signal detection may occur;

FIG. 12 is a block diagram showing how multiple APD circuits may be used for a series of power amplifiers in a transmission chain;

FIG. 13 illustrates how different portions of an open-loop APD circuit may be implemented between a digital circuit and an analog circuit;

FIG. 14 is a phase versus power graph showing how the phase distortion may vary between a phase advancement and a phase delay across the power range;

FIG. 15 is a block diagram showing how multiple APD circuits may be used to provide piecewise phase adjustments;

FIG. 16 is a graph showing how a varactor's capacitance may change as a function of voltage or power, illustrating the suitability of use of varactors in an APD circuit;

FIG. 17 is a block diagram showing how the varactor of FIG. 16 may be implemented in an APD circuit;

FIG. 18 is a block diagram showing how N-type field-effect transistors (FETs) (NFETs) may be used as varactors in an APD circuit;

FIG. 19 is a block diagram of an alternate arrangement of NFET varactors used in an APD circuit;

FIG. 20 is a graph of amplitude-to-amplitude gain as a function of activity by the APD circuit compared to a graph of the amplitude-to-phase behavior as a function of the APD circuit showing how the functions are essentially orthogonal;

FIG. 21 is a block diagram of an exemplary transmission chain having an output-sensing APD circuit used to offset amplitude distortion in the transmission chain;

FIG. 22 is a block diagram of an exemplary transmission chain having an input-sensing APD circuit used to offset amplitude distortion in the transmission chain;

FIG. 23 is a block diagram of an exemplary transmission chain having an interstage-sensing APD circuit used to offset amplitude distortion in the transmission chain;

FIG. 24 is a block diagram of an exemplary transmission chain having multiple APD circuits with different sensing points used to offset amplitude distortion in the transmission chain;

FIGS. 25-27 illustrate power versus amplitude distortion graphs showing exemplary possible distortion characteristics for which correction may be applied;

FIG. 28 is a block diagram of an exemplary transmission chain having multiple sensing circuits and multiple APD circuits used to offset complexly-shaped amplitude distortion profiles such as those shown in FIGS. 25-27;

FIG. 29 is a block diagram of a hybrid transmission chain where some elements are implemented in a complementary metal oxide semiconductor (CMOS) die and some elements are implemented in a III-V periodic material type die;

FIG. 30 is a block diagram of a transmission chain with a predistortion circuit that may control a bias for a single gain stage of the power amplifier or multiple gain stages;

FIG. 31 is a transmission chain showing details of an exemplary bias circuit that may provide predistortion according to an aspect of the present disclosure;

FIG. 32 is a block diagram of a transmission chain showing details of an alternate exemplary bias circuit that may provide predistortion according to an aspect of the present disclosure;

FIG. 33 is a block diagram of a bias circuit that may be used to control bias signals to a power amplifier according to exemplary aspects of the present disclosure;

FIG. 34 is a graph showing where different power sources may be used by the bias circuit of FIG. 33;

FIG. 35 is a block diagram of the bias circuit of FIG. 33 with a current source in place of a voltage source to assist in providing bias signals to the power amplifier;

FIG. 36 is a graph showing how linear operation of the bias signals may operate for the power amplifier;

FIG. 37 is a block diagram of the bias circuit of FIG. 33 with piecewise linear bias signal circuitry to provide differently-sloped bias signals based on power supply levels;

FIG. 38 is a graph illustrating one possible piecewise linear approach to bias signals with a floor to prevent collapse of the power amplifier;

FIG. 39 is a block diagram of the bias circuit of FIG. 33 with a limiter circuit to keep the floor in the graph of FIG. 38;

FIG. 40 is a graph illustrating another possible piecewise linear approach with a single inflection point for the bias function;

FIG. 41 is a graph illustrating another possible piecewise linear approach with multiple inflection points for the bias function;

FIG. 42 is a block diagram of the bias circuit of FIG. 33 interoperating with over power protection circuitry to debias a power amplifier;

FIG. 43 is a block diagram of a first exemplary aspect of the bias circuit of FIG. 33 interoperating with over power protection circuitry and linearization circuitry; and

FIG. 44 is a block diagram of a second exemplary aspect of the bias circuit of FIG. 33 interoperating with over power protection circuitry and linearization circuitry.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed herein include bias circuits for power amplifiers. In an exemplary aspect, a bias circuit may select between different power sources based on a power need for the power amplifier. As voltage levels between the different power sources may differ at the moment of transition, additional circuitry is provided to smooth the transition between the differing power levels. Further, the bias circuit may provide bias signals to multiple stacked transistors in a power amplifier in such a manner so as to avoid collapsing any of the transistors. One such approach is a piecewise linear bias signal. Still further, the bias circuit may interoperate with predistortion circuitry to assist in linear operation of the power amplifier. Still further, the bias circuit may interoperate with protection circuitry to prevent over current, over voltage, or over power conditions that may damage the power amplifier. As a nuance, the bias circuit may balance the demands of linear operation against the need to protect the power amplifier. Such a bias circuit that interoperates effectively with protection and linearization circuitry while providing smooth bias signals to the power amplifier may improve overall efficiency of the power amplifier and assist in meeting wireless protocol requirements.

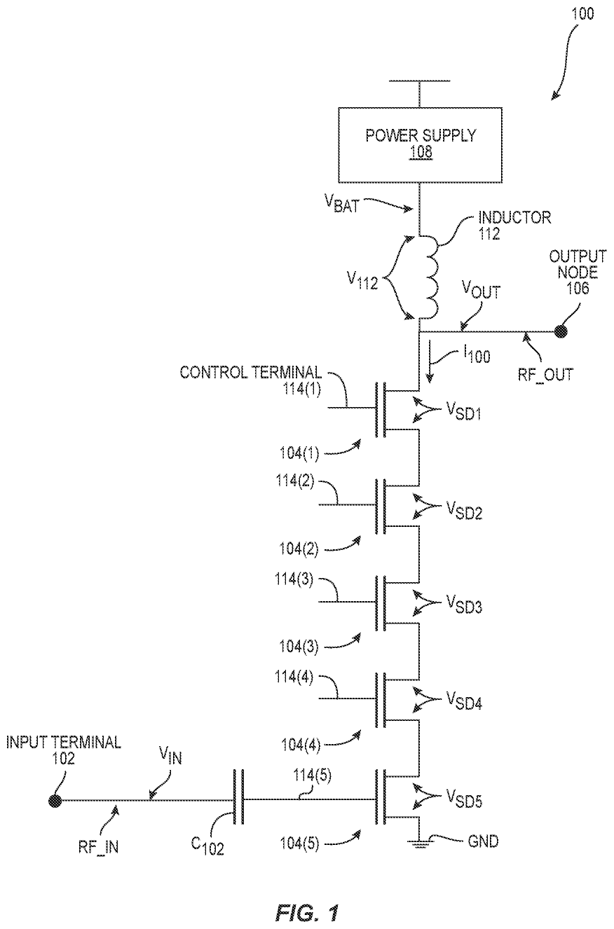

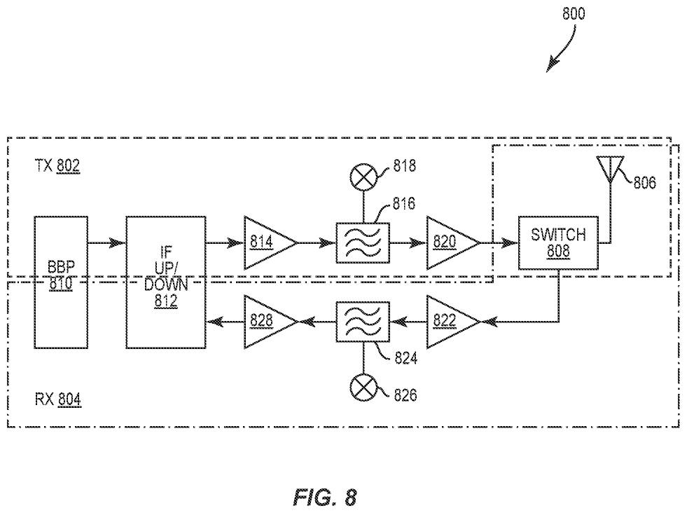

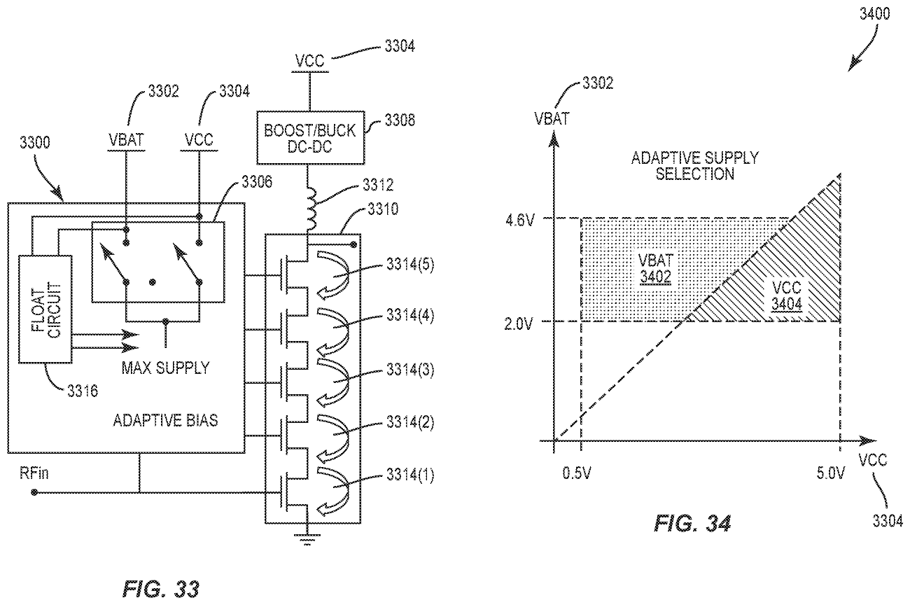

Before addressing exemplary aspects of the bias circuit of the present disclosure, a discussion of some of the burdens put on power amplifiers is provided followed by a discussion of possible protection circuits that may be used with power amplifiers beginning with reference to FIG. 1. Such protection circuits rely on the presence of a bias circuit such as one contemplated by the present disclosure. A discussion of a transmission chain that uses a power amplifier begins with reference to FIG. 8. Such power amplifiers may suffer from non-linearities which are corrected through predistortion circuits. A discussion of such predistortion circuits that assist in providing linear operation follows. Again, the ability to assist in linearizing the power amplifier is facilitated by a bias circuit such as one contemplated by the present disclosure. A discussion of some of the particulars of the bias circuit of the present disclosure begins below with reference to FIG. 33.

Telecommunication networks are not immediately and simultaneously updated in all geographical areas as a new generation of telecommunication technology emerges. Therefore, mobile devices may need to include transmitters and receivers that operate in a variety of networks. In the evolution from second generation (2G) to third generation (3G), fourth generation long-term evolution (4G LTE), and fifth generation new radio (5G NR), the power demands of transmitters in mobile devices have changed. At the same time, the consumer market has continued to demand smaller and cheaper devices. Both the size and cost of power amplifiers in a wireless transmitter can be reduced by transitioning from amplifier circuits with larger and more expensive transistors, such as bipolar junction transistors (BJTs) made of gallium arsenide (GaAs), for example, to lower-voltage transistors. As an example, the lower-voltage transistors may be silicon transistors, such as field-effect transistors (FETs) (e.g., metal-oxide-semiconductor (MOS) FETs (MOSFETs)). FETs comprises a gate, a first source/drain, and a second source/drain. A bias voltage on the gate controls flow of current between the first source/drain and the second source/drain.

Previous amplifier circuits made with GaAs BJTs require one or a few transistors that can handle large voltages. However, such large voltages would be destructive to the lower-voltage transistors. To overcome this problem, an amplifier circuit can include a plurality of voltage transistors with a lower voltage limit coupled in series between an output node and a reference voltage node. The output voltage of a cascode amplifier circuit is distributed across multiple transistors, such that voltage stresses to each transistor are reduced, and damage to the individual transistors may be avoided. With this type of amplifier circuit, the output voltage levels needed in each different generation of telecommunication technology may be achieved at a lower cost and in a smaller package. However, such cascode amplifier circuits pose additional challenges.

FIG. 1 is an illustration of an example of a cascode amplifier circuit 100 (“amplifier circuit 100”). The amplifier circuit 100 includes an input terminal 102 on which an input radio frequency (RF) signal RF_IN is received through a capacitor C₁₀₂. The input RF signal RF_IN is an analog signal amplified by cascode transistors 104(1)-104(5) based on a gain of the last cascode transistor 104(5) to generate an RF output signal RF_OUT having an output voltage V_{OUT} on an output node 106. The cascode transistors 104(1)-104(5) are coupled in series between the output node 106 and a reference voltage node (e.g., ground voltage node) GND. Although the amplifier circuit 100 in this example includes only five of the cascode transistors 104(1)-104(5), an amplifier circuit in a power amplification circuit as disclosed herein may include fewer or more cascode transistors coupled in series. The amplifier circuit 100 may include cascode transistors 104(1)-104(5) that are all of a first type, such as all N-channel FETs (NFETs) or all P-channel FETs (PFETs). Alternatively, an amplifier circuit of a power amplification circuit as disclosed herein may be a complementary circuit including both NFETs and PFETs.

The amplifier circuit 100 is powered by a power supply 108, such as a battery providing a supply voltage V_{BAT}. The amplifier circuit 100 includes an inductor 112 coupled between the power supply 108 and the output node 106. A current I₁₀₀ through the cascode transistors 104(1)-104(5) increases and decreases in response to changes in a voltage V_{IN} on the input terminal 102. Control terminals 114(1)-114(5) (e.g., gates) of the cascode transistors 104(1)-104(5) are biased to keep the cascode transistors 104(1)-104(5) turned on (e.g., in a saturation region) to conduct the current I₁₀₀. An inductor voltage V₁₁₂ is induced across the inductor 112 in response to changes in the current I₁₀₀. Thus, the output voltage V_{OUT} on the output node 106 is equal to the supply voltage V_{BAT} plus the inductor voltage V₁₁₂ (V_{OUT}=V_{BAT}+V₁₁₂). In this manner, the output voltage V_{OUT} can exceed twice the supply voltage V_{BAT} (i.e., V_{OUT}>2xV_{BAT}). Since the output voltage V_{OUT} is distributed across source-to-drain voltages V_{SD1}-V_{SD5}, in the case of the cascode transistors 104(1)-104(5) comprising FETs, the output voltage V_{OUT} is the total of the source-to-drain voltages V_{SD1}-V_{SD5}. In some cases, the output voltage V_{OUT} may not be equally divided among the source-to-drain voltages V_{SD1}-V_{SD5}. Thus, at a peak in magnitude of the output voltage V_{OUT}, a destructive voltage level may be applied across one or more of the cascode transistors 104(1)-104(5).

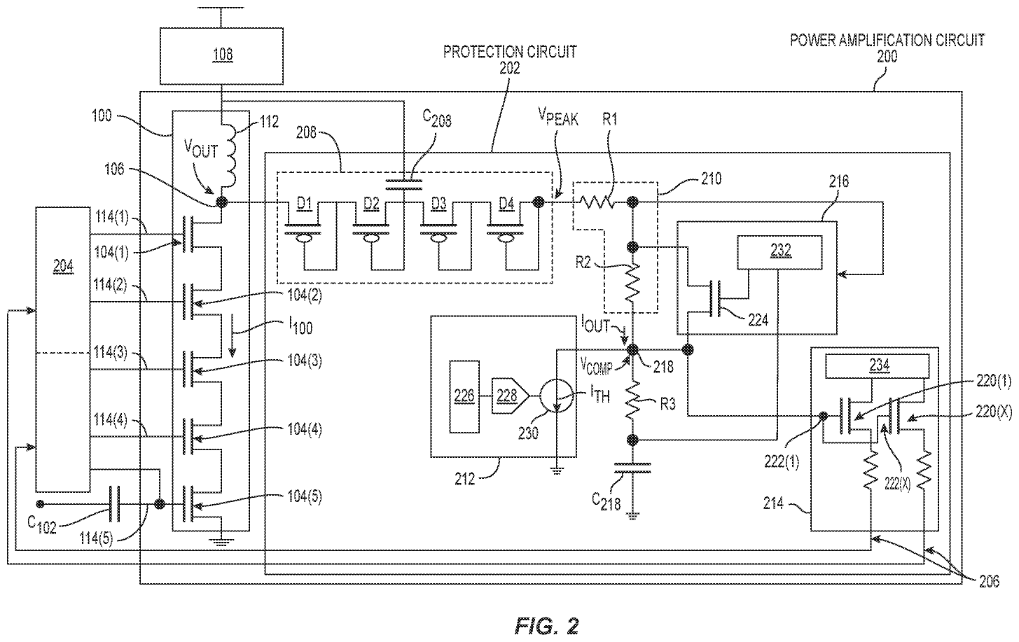

FIGS. 2, 3, and 5-7 are illustrations of examples of power amplification circuits, including circuits that protect the cascode transistors 104(1)-104(5) by adjusting bias voltages on at least one of the control terminals 114(1)-114(5) upon detecting that the output voltage V_{OUT} exceeds a threshold.

FIG. 2 is an illustration of a power amplification circuit 200, including the amplifier circuit 100 of FIG. 1 and a protection circuit 202. Details of the amplifier circuit 100 are shown in FIG. 1. FIG. 2 also includes a bias circuit 204 coupled to the power amplification circuit 200. The bias circuit 204 is an example of a circuit that is coupled to the control terminals 114(1)-114(5) to provide bias voltages for controlling the cascode transistors 104(1)-104(5). More detail about the bias circuit 204 constructed and operating according to exemplary aspects of the present disclosure is provided below with reference to FIG. 33. The protection circuit 202 provides one or more feedback signals 206 to the bias circuit 204 in response to detecting that the output voltage V_{OUT} exceeds a threshold. The protection circuit 202 provides the one or more feedback signals 206 to control the bias circuit 204 to adjust the bias voltages provided to the control terminals 114(1)-114(5). In particular, the one or more feedback signals 206 reduce the bias voltage on at least the control terminal 114(5). In some examples, the one or more feedback signals 206 cause other control terminals 114(1)-114(4), such as the control terminal 114(4), to also be adjusted. Providing feedback to adjust the bias voltage(s) on one or more of the control terminals 114(1)-114(5) reduces the current I₁₀₀ through the amplifier circuit 100, which reduces the possibility of destructive voltages being applied to the cascode transistors 104(1)-104(5).

Before providing details of each of the features of the protection circuit 202, a brief description of the operation of the protection circuit 202 is provided. The protection circuit 202 includes a peak voltage circuit 208 coupled to the output node 106. The peak voltage circuit 208 generates a peak voltage V_{PEAK}, which indicates a highest magnitude of the output voltage V_{OUT}. The peak voltage V_{PEAK} is provided to a voltage-to-current circuit 210 that generates an output current I_{OUT} based on the peak voltage V_{PEAK}. The protection circuit 202 also includes a threshold current circuit 212 that generates a threshold current I_{TH} based on a threshold value. The output current I_{OUT} is compared to the threshold current I_{TH} to determine whether the output voltage V_{OUT} is above a desired (i.e., threshold) level. Specifically, the protection circuit 202 includes a feedback circuit 214 and an acceleration circuit 216 that respond to the output current I_{OUT} being higher than the threshold current I_{TH}. The feedback circuit 214 generates the one or more feedback signals 206. The acceleration circuit 216 increases the responsiveness of the protection circuit 202, so the feedback circuit 214 will respond more quickly and/or to a stronger degree when, for example, the output current I_{OUT} is significantly higher than the threshold current I_{TH}. The features of the protection circuit 202 and their individual operation details are described further below.

The peak voltage circuit 208 includes diodes D1-D4 coupled in series with the anode of the first diode D1 coupled to the output node 106 and the cathode of the last diode D4 coupled to the voltage-to-current circuit 210. The peak voltage circuit 208 also includes a capacitor C₂₀₈ with one terminal coupled to the power supply 108. The other terminal of the capacitor C₂₀₈ is coupled to the cathode of diode D2 and the anode of diode D3. The peak voltage V_{PEAK} is a voltage on the cathode of the last diode D4. The peak voltage V_{PEAK} provided to the voltage-to-current circuit 210 is lower than the actual output voltage V_{OUT} due to voltage drops across the diodes D1-D4 but is based on the output voltage V_{OUT}. In some examples, the diodes D1-D4 are MOS diodes (e.g., P-channel MOS diodes).

The voltage-to-current circuit 210 includes a first resistor R1 in series with a second resistor R2. The first resistor R1 may be much larger than the second resistor R2, the same size, or smaller than the second resistor R2. The voltage-to-current circuit 210 generates the output current I_{OUT} on a comparison node 218 based on the peak voltage V_{PEAK}. The output current I_{OUT} may be proportional to the peak voltage V_{PEAK}. In some examples, the output current I_{OUT} is determined by a difference in voltage between the peak voltage V_{PEAK} and a voltage V_{COMP} on the comparison node 218 and also on the total resistance of the resistors R1 and R2. In this way, the magnitude of the output current I_{OUT} on the comparison node 218 corresponds to the magnitude of the peak voltage V_{PEAK} and, therefore, corresponds to the output voltage V_{OUT}.

The threshold current circuit 212 conducts the threshold current I_{TH} that corresponds in magnitude to the output current I_{OUT} generated when the output voltage V_{OUT} has reached a desired maximum. Beyond the desired maximum of the output voltage V_{OUT}, destructive voltages may be applied to the cascode transistors 104(1)-104(5). In other words, if the output current I_{OUT} is greater than the threshold current I_{TH}, the output voltage V_{OUT} may be high enough to cause destructive voltages on at least one of the cascode transistors 104(1)-104(5). In this context, a destructive voltage can cause permanent physical damage. In this example, the threshold current circuit 212 includes a threshold register 226 configured to store the threshold value. The threshold register 226 is coupled to a digital-to-analog converter (DAC) 228 that generates an analog control signal based on the threshold value. The analog control signal controls a current generator circuit 230 to conduct the threshold current I_{TH} from the comparison node 218.

The protection circuit 202 also includes a resistor R3 coupled to the comparison node 218 and a capacitor C₂₁₈ coupled between the resistor R3 and the reference voltage node GND. The resistor R3 and the capacitor C₂₁₈ create a zero in the response of the feedback circuit 214. Current through the comparison node 218 that is not conducted through the threshold current circuit 212 may be conducted through the resistor R3 and the capacitor C₂₁₈.

The output current I_{OUT} may be compared to the threshold current I_{TH} to determine whether the output voltage V_{OUT} has exceeded the desired maximum. In addition, when the output current I_{OUT} exceeds the threshold current I_{TH}, the voltage V_{COMP} on the comparison node 218 increases. In this manner, the feedback circuit 214 detects whether the output current I_{OUT} exceeds the threshold current I_{TH}. If an increase of the voltage V_{COMP} is detected by the feedback circuit 214, the feedback circuit 214 generates the one or more feedback signals 206 to the bias circuit 204 to reduce the bias voltage(s) on one or more of the control terminals 114(1)-114(5). In more detail, the feedback circuit 214 includes at least one transistor 220(1)-220(X) coupled to a circuit 234, where X is an integer value. In some examples, the integer X may correspond to the number of cascode transistors in the amplifier circuit 100. Thus, in the example of the cascode transistors 104(1)-104(5), X may be any integer from 1 to 5. In some examples, the circuit 234 may control power supplied to the at least one transistor 220(1)-220(X). Gate terminals 222(1)-222(X) of the at least one transistor 220(1)-220(X) may be coupled to the comparison node 218 and receive the voltage V_{COMP}. The voltage V_{COMP} of the comparison node 218 remains at a known level while the output current I_{OUT} is less than or equal to the threshold voltage I_{TH}. If the output current I_{OUT} increases above the threshold voltage I_{TH}, the voltage V_{COMP} will increase, and the bias voltage(s) on the gate terminals 222(1)-222(X) increases, which causes the current of the one or more feedback signals 206 provided to the bias circuit 204 to also increase. In response, the bias circuit 204 reduces a bias voltage on the control terminal 114(5) of the last cascode transistor 104(5) and may also reduce a bias voltage on one or more of the cascode transistors 104(1)-104(4).

The acceleration circuit 216 includes a bypass transistor 224 that couples to terminals of the resistor R2 of the voltage-to-current circuit 210 to bypass the resistor R2 when the acceleration circuit 216 detects that the output current I_{OUT} exceeds a predetermined stress level. In some examples, the stress level may be determined by a voltage between the resistors R1 and R2 of the voltage-to-current circuit 210. In some examples, the stress level may be determined by a current through the resistor R3. In this regard, the acceleration circuit 216 may be coupled to the resistor R3 and the capacitor C₂₁₈. The stress level may be indicated by a stress value stored in a register 232. The acceleration circuit 216 may activate the bypass transistor 224 when either the voltage V_{COMP} increases or when the acceleration circuit 216 determines that the output current I_{OUT} is greater than the stress level. In some examples, the acceleration circuit 216 activates the bypass transistor 224 when it is determined that the output current I_{OUT} exceeds the threshold current I_{TH} by a predetermined margin. Activating the bypass transistor 224 reduces a resistance in the voltage-to-current circuit 210, which increases the output current I_{OUT} for a given voltage. A lower resistance between the peak voltage circuit 208 and the comparison node 218 increases the current to the comparison node 218, which increases the speed and/or magnitude of the response by the feedback circuit 214.

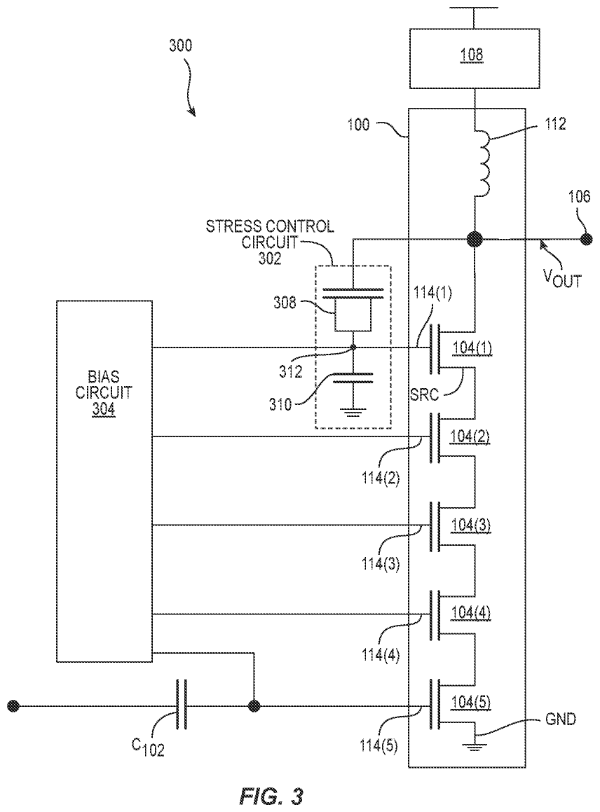

FIG. 3 is an illustration of a power amplification circuit 300, including the amplifier circuit 100 of FIG. 1 and a stress control circuit 302 that protects the cascode transistors 104(1)-104(5) by adjusting bias voltages on at least one of the control terminals 114(1)-114(5) upon detecting that the output voltage V_{OUT} exceeds a threshold. The threshold to which the stress control circuit 302 responds may be the same threshold or a different threshold than the threshold discussed above, to which the feedback circuit 214 responds. FIG. 3 also includes a bias circuit 304 that provides bias voltages for controlling the cascode transistors 104(1)-104(5). Again, details of the bias circuit 304 are discussed below with reference to FIG. 33.

The stress control circuit 302 includes a variable capacitor 308 and a fixed capacitor 310 coupled in series between the output node 106 and the reference voltage node GND. The variable capacitor 308 may also be a varactor or bipolar junction device. The control terminal 114(1) of the first cascode transistor 104(1) is coupled to a bias node 312 between the variable capacitor 308 and the fixed capacitor 310. For example, in FIG. 3, the variable capacitor 308 is coupled between the output node 106 and the bias node 312. In addition, in the example shown in FIG. 3, the variable capacitor 308 may be a MOS varactor. The fixed capacitor 310 is coupled between the bias node 312 and the reference voltage node GND. As the output voltage V_{OUT} on the output node 106 increases, the variable capacitor 308 coupled to the output node 106 increases in capacitance. As the variable capacitor 308 increases in capacitance, a ratio of capacitance between the variable capacitor 308 and the fixed capacitor 310 increases, causing a bias voltage at the bias node 312 to increase. In the example in which the first cascode transistor 104(1) is an N-channel MOSFET (NFET), the control terminal 114(1) is a gate 114(1), and the output node 106 is a drain terminal 106. Raising the bias voltage on the gate 114(1) raises the voltage on a source terminal SRC of the NFET cascode transistor 104(1) based on a gate-to-source voltage. Raising the voltages on the gate 114(1) and the source terminal SRC as the drain terminal 106 of the first cascode transistor 104(1) increases is referred to herein as “floating up” the first cascode transistor 104(1). By increasing the voltage on the source terminal SRC, the voltage drop from the drain terminal 106 to the source terminal SRC is reduced, which avoids a destructive voltage being applied between the drain terminal 106 and the source terminal SRC of the first cascode transistor 104(1). In some examples, the stress control circuit 302 may include a second variable capacitor (not shown) and a second fixed capacitor (also not shown) coupled in series between the output node 106 and the reference voltage node GND with the control terminal 114(2) coupled to a node between the second variable capacitor and the second fixed capacitor to adjust the bias voltage of the cascode transistor 104(2). Although not shown here, the stress control circuit 302 may also include a signal or signals provided to the bias circuit 304 to prevent the bias circuit 304 from reducing the bias voltage on the control terminal 114(1), and possibly one or more other control terminals 114(2)-114(5), in conflict with the stress control circuit 302.

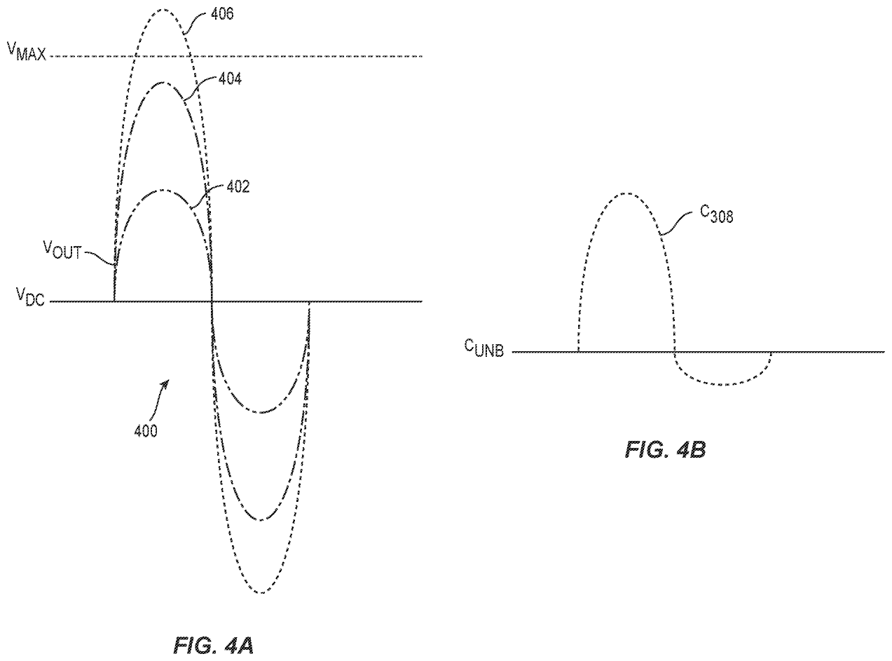

An illustration of the effect of the stress control circuit 302 is provided in FIGS. 4A and 4B. FIG. 4A is a graph 400 illustrating the output voltage V_{OUT} for signals 402, 404, and 406, whose voltages vary in time with respect to a direct current (DC) voltage V_{DC}. A maximum voltage V_{MAX} is also shown in FIG. 4A. If the output voltage V_{OUT} is above the maximum voltage V_{MAX}, the output voltage V_{OUT} will cause a destructive voltage across one or more of the cascode transistors 104(1)-104(5) in the amplifier circuit 100 in FIG. 1. Voltages below the DC voltage V_{DC} do not cause destructive voltages in the amplifier circuit 100. Therefore, when the signals 402, 404, and 406 have low values that cannot cause destructive voltages to the cascode transistors 104(1)-104(5), there is no need to change a capacitance C₃₀₈ of the variable capacitor 308 with the output voltage V_{OUT} below the DC voltage V_{DC}. As shown, the signals 402 and 404 do not reach a high enough voltage to cause a destructive voltage. However, the signal 406 exceeds the maximum voltage V_{MAX}. The stress control circuit 302 of FIG. 3 responds to increases in the output voltage V_{OUT} by increasing the capacitance C₃₀₈ of the variable capacitor 308 to raise a bias voltage on the control terminal 114(1) of the first cascode transistor 104(1).

FIG. 4B is an illustration of the capacitance C₃₀₈ of the variable capacitor 308 as it changes relative to an unbiased capacitance C_{UNB} in response to the rise and fall of the signal 406 due to the stress control circuit 302 (not shown here). As shown, the capacitance C₃₀₈ of the variable capacitor 308 is non-linear, meaning that the response to the output voltage V_{OUT} above the DC voltage V_{DC} differs from the response to the output voltage V_{OUT} below the DC voltage V_{DC}. Specifically, the decrease to the capacitance C₃₀₈ caused by the stress control circuit 302 due to a drop in the signal 406 below the DC voltage V_{DC} is much less than a corresponding increase of the capacitance C₃₀₈ due to a rise in the signal 406 above the DC voltage V_{DC}. In this manner, the stress control circuit 302 changes the bias voltage on the first cascode transistor 104(1) as needed and does not change the bias voltage on the first cascode transistor 104(1) when none is needed.

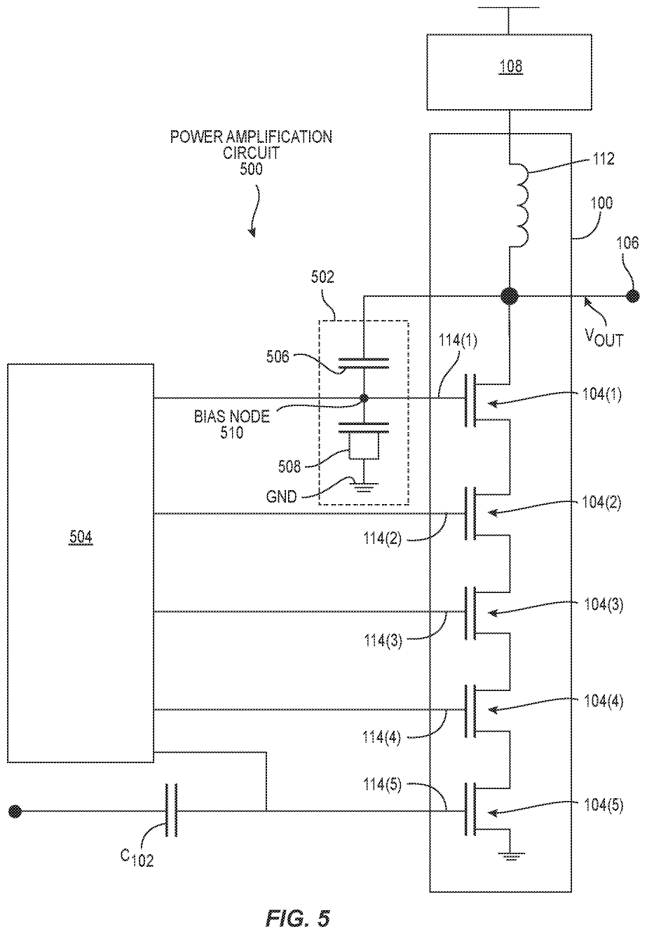

FIG. 5 illustrates an alternative example of a power amplification circuit 500, including the amplifier circuit 100 and a stress control circuit 502. FIG. 5 also includes a bias circuit 504 that provides bias voltages for controlling the cascode transistors 104(1)-104(5). As with the bias circuits 204 and 304, more details about the bias circuit 504 may be found below with reference to FIG. 33. The stress control circuit 502 adjusts the bias voltage on at least one of the control terminals 114(1)-114(5) in response to the output voltage V_{OUT} exceeding a threshold. The stress control circuit 502 includes a fixed capacitor 506 and a variable capacitor 508 coupled in series between the output node 106 and the reference voltage node GND. The variable capacitor 508 may also be a varactor. The control terminal 114(1) of the first cascode transistor 104(1) is coupled to a bias node 510 between the variable capacitor 508 and the fixed capacitor 506. In the example in FIG. 5, the fixed capacitor 506 is coupled between the output node 106 and the bias node 510. The variable capacitor 508 is coupled between the bias node 510 and the reference voltage node GND. In addition, in the example shown in FIG. 5, the variable capacitor 508 may be a varactor diode. As the output voltage V_{OUT} on the output node 106 increases, raising the bias voltage on the control terminal 114(1), the variable capacitor 508 decreases in capacitance. As the capacitance of the variable capacitor 508 decreases, the ratio of the fixed capacitor 506 and the variable capacitor 508 decreases, and the bias voltage is further increased.

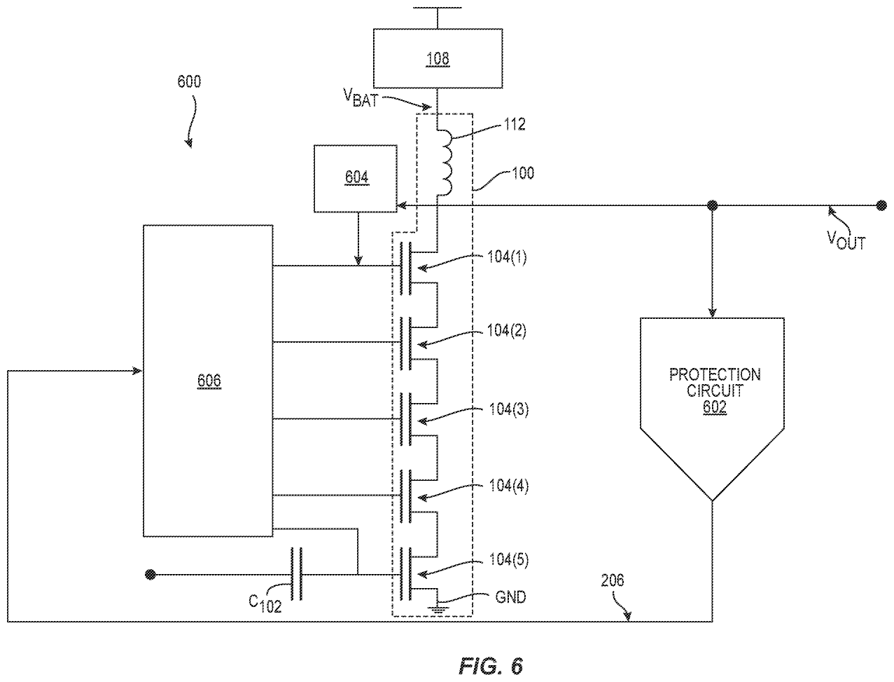

FIG. 6 is an example of a power amplification circuit 600, including the amplifier circuit 100, a protection circuit 602 corresponding to the protection circuit 202 in FIG. 2, and a stress control circuit 604 corresponding to one of the stress control circuits 302 and 502 in FIGS. 3 and 5, respectively. FIG. 6 also includes a bias circuit 606. Like the bias circuits 204, 304, and 504, more detail about the bias circuit 606 may be found below with reference to FIG. 33. In response to the output voltage V_{OUT} rising above a voltage at which destructive voltages may be supplied to the cascode transistors 104(1)-104(5), the protection circuit 602 provides a feedback signal 206 that reduces a bias voltage of at least the last cascode transistor 104(5), and the stress control circuit 604 raises a bias voltage of the first cascode transistor 104(1). The protection circuit 602 reduces the bias voltage of at least the last cascode transistor 104(5) to a bias voltage closer to the reference voltage of the reference voltage node GND (e.g., ground). In contrast, the stress control circuit 604 increases the bias voltage of at least the first cascode transistor 104(1) to a level closer to the supply voltage (V_{BAT}).

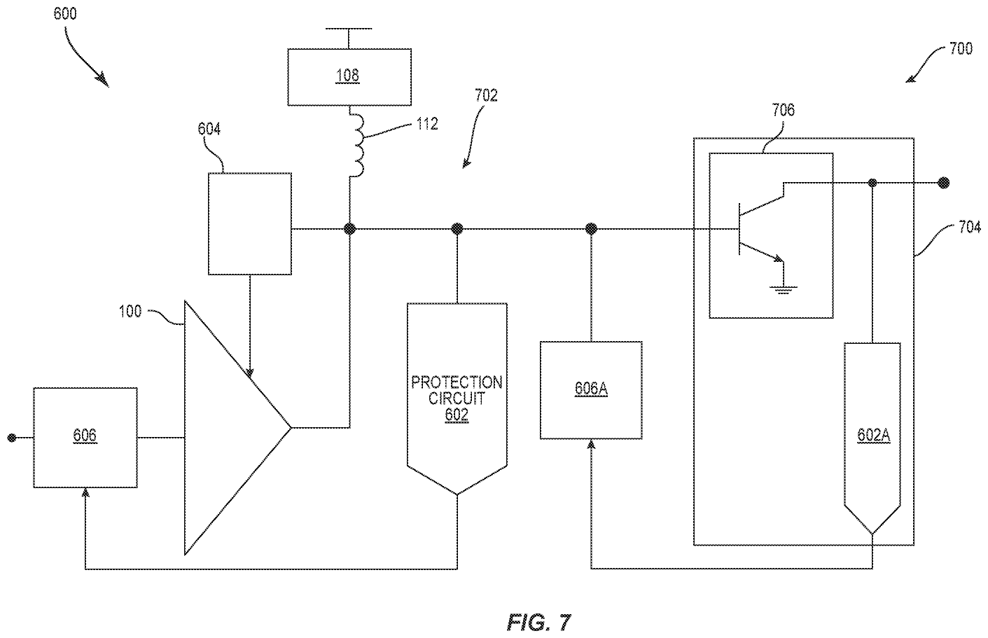

FIG. 7 is an example of a power amplification circuit 700 to show that the power amplification circuit 600 of FIG. 6, including the amplifier circuit 100, the protection circuit 602, and the stress control circuit 604, coupled to the bias circuit 606, may be a first stage 702 of a multi-stage amplifier. FIG. 7 also shows that the power amplification circuit 700 can include a second stage 704. In this example, the second stage 704 includes an amplification stage 706 and a protection circuit 602A coupled to a bias circuit 606A. The second stage 704 may also or alternatively include the stress control circuit 604 (corresponding to the stress control circuit 302 in FIG. 3 or the stress control circuit 502 in FIG. 5). Thus, as disclosed herein, cascode amplifiers and/or other types of amplifier stages may be protected from destructive voltages.

In addition to the concerns regarding power amplifiers with respect to over voltage conditions discussed in FIGS. 1-7, there may be concerns about over current, over power, over temperature, or other conditions which would potentially damage operation of transistors forming a power amplifier. The authors of the present disclosure have also authored disclosures addressing such conditions (e.g., the '280 application listed in the related applications at the beginning of the disclosure). In many cases, the solutions provided are based on use of a bias circuit. Exemplary aspects of the present disclosure provide details about possible bias circuits suitable for use in such instances. Further, there may be concerns about operation of the power amplifiers in transmission chains and particularly how nonlinear operation of a power amplifier may negatively impact performance of the transmission chain. As described below, in many instances a bias circuit may be used to address such concerns. The bias circuits according to exemplary aspects of the present disclosure are also suitable to address such concerns. Before providing details about such bias circuits, a discussion of the nonlinear operation and possible solutions are provided with reference to FIGS. 8-32.

In this regard, FIG. 8 illustrates a transceiver 800 having a transmission chain 802 and a receiver chain 804 that share an antenna 806 and a switch 808. Additional common elements may include a baseband processor (BBP) 810 and/or an intermediate frequency (IF) processor 812. Signals to be transmitted are generated in the BBP 810 and passed to the IF processor 812, which upconverts the baseband frequency to an IF signal. The IF signal may be amplified by a preamplifier stage 814. The amplified IF signal may be filtered by a filter stage 816, which may also interoperate with an oscillator 818 to upconvert to an RF signal. The filter stage 816 may apply additional filtering to the RF signal. The RF signal may then be amplified by a power amplifier stage 820, which may include a driver stage, an output stage, and/or an intermediate stage (not shown). In an exemplary aspect, the power amplifier stage 820 may include the amplifier circuit 100 described in the previous Figures. The amplified RF signal may be passed to the switch 808 for transmission through the antenna 806. In an exemplary aspect, the switch 808 may be a duplexer or the like.

The antenna 806 may also receive RF signals. Such received signals are passed to the switch 808, which passes the received RF signals to a low noise amplifier (LNA) 822. The amplified signals are passed to a filter stage 824, which filters the received signal and interoperates with an oscillator 826 to downcovert the RF signal to an IF signal. The oscillator 826 may be the same as the oscillator 818. The filter stage 824 may filter the IF signal as well before passing the IF signal to an IF amplifier 828, which amplifies the IF signal before passing the amplified IF signal to the IF processor 812, which downconverts the signal to a baseband signal, which is processed by the BBP 810. As is readily apparent, there are several places where amplifying elements may be present. While most of the discussion focuses one or more transmission amplifiers, aspects of the present disclosure may be applicable to any of the amplifying elements.

It should be appreciated that other combinations of elements may also be used to form a transmission chain, and the elements in FIG. 8 are intended to illustrate a context for the present disclosure and not limit the claimed aspects. For example, a transmission chain may eliminate the use of IF signals without departing from the scope of the present disclosure. As another readily contemplated aspect, the IF processor 812 and the BBP 810 may be combined.

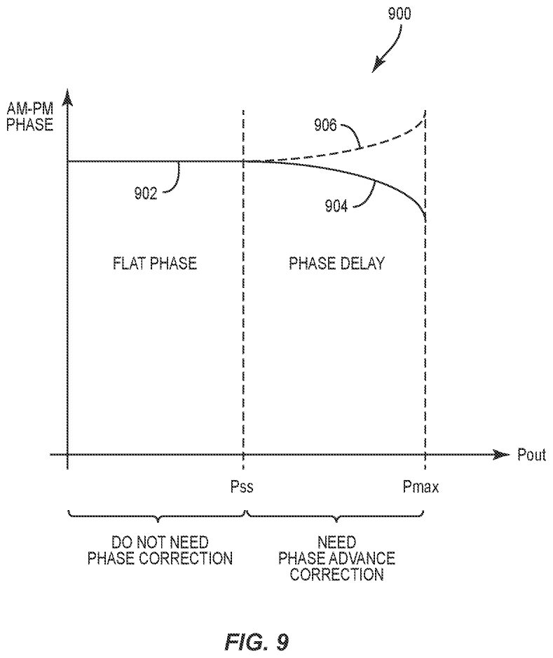

To provide desired operation, the elements of the transmission chain 802 and the receiver chain 804 (and particularly the amplifying elements) should have a generally linear operation profile. However, many of these elements are not linear over large frequency ranges. With the advent of large bandwidth operating ranges in new generations of cellular standards, providing linearity over the entire frequency range and/or power range is increasingly difficult. This difficulty is particularly true for power amplifiers, which may introduce phase distortion over a portion of the power range as illustrated in FIG. 9. Specifically, FIG. 9 illustrates graph 900, which shows the overall phase characteristic with exemplary phase distortion at large power levels. That is, at power levels below Pss, the phase is relatively flat as shown by line segment 902. However, at power levels above Pss, extending up to Pmax, the phase begins to delay as shown by line segment 904. Line segment 906 shows a needed correction to return to linear operation. Graph 900 is provided as an example, and other power amplifiers may have phase advancement at high power and need phase delay added.

While some linearity may be provided by increasing current to the power amplifier to operate as a class-AB amplifier, this increased current use degrades overall efficiency of the power amplifier. Another option is the concept of digital predistortion (DPD). Such DPD occurs in the BBP 810 and may require complex interoperation with the power amplifiers 814, 820. Alternatively, the BBP 810 may include extensive tables with various operating parameters and the desired predistortion values based on the numerous operating parameters. As the bandwidths in question become larger in new wireless standards, existing solutions become less effective and provide opportunities for innovation.

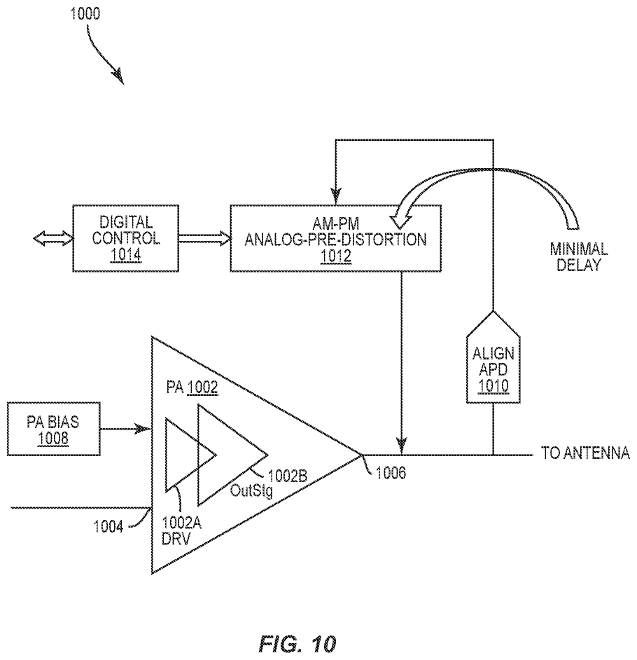

One solution advanced by the authors of the present disclosure contemplates analog predistortion (APD) of the phase using an open-loop feedback circuit that minimizes delay between measuring the phase distortion and correction. A high-level block diagram of this solution is provided in FIG. 10. Additional details are provided in subsequent figures.

With reference to FIG. 10, a transmission chain 1000 is shown. Particularly, a power amplifier stage 1002 is shown that amplifies an RF signal received at an input 1004 before passing the amplified signal to an antenna (not shown) from an output 1006. It should be appreciated that the input 1004 and the output 1006 may be considered nodes. While the input 1004 and the output 1006 are shown as single ended, it should be appreciated that these could be differential without departing from the scope of the present disclosure. For ease in explanation, subsequent examples will also use single-ended architectures with the understanding that differential or quadrature could be used as needed or desired.

The power amplifier stage 1002 may include one or more sub-stages such as a driver stage 1002A and an output stage 1002B. The power amplifier stage 1002 receives a bias signal from a bias circuit 1008. A detection and alignment circuit 1010 may be associated with the power amplifier stage 1002 to detect a phase of signals. The detection and alignment circuit 1010 may communicate with an amplitude modulation (AM)-to-phase modulation (PM) (AM-PM) predistortion circuit 1012. The AM-PM predistortion circuit 1012 is expected to be an analog circuit and thus may be represented by an acronym APD. The AM-PM predistortion circuit 1012 may interoperate with a digital controller 1014 as explained in greater detail below. Based on communication from the detection and alignment circuit 1010, the AM-PM predistortion circuit 1012 injects a correction signal to compensate for phase distortion. As explained in greater detail below, the correction signal may be a phase advance correction signal or a phase delay correction signal. Collectively, the detection and alignment circuit 1010 with the AM-PM predistortion circuit 1012 form an open-loop feed forward APD phase correction block that will work with a bias circuit to set a quiescent point of the AM-PM predistortion circuit 1012 such that either a phase advance or a phase delay correction is generated.

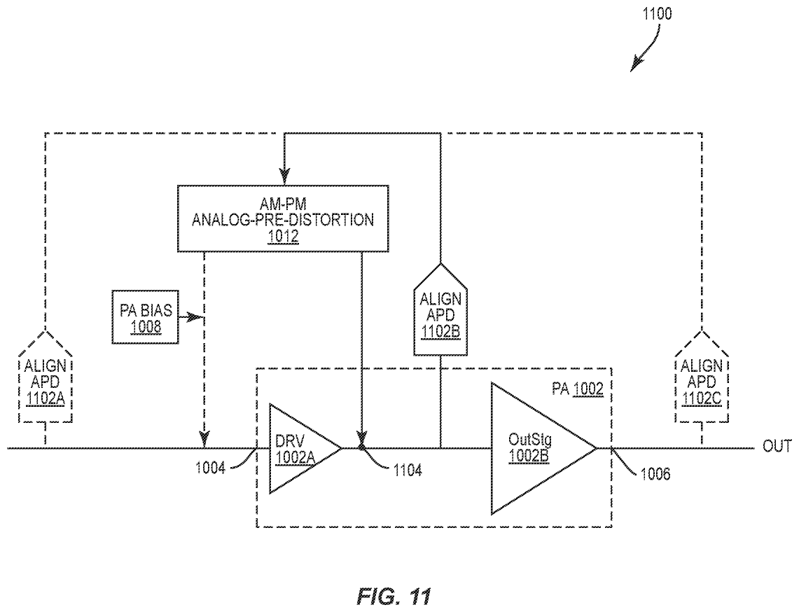

Depending on the structure of the power amplifier stage 1002, the precise placement of the detection and alignment circuit 1010 and the place where the correction signal is injected may be varied as better seen in FIG. 11. In this regard, FIG. 11 illustrates a transmission chain 1100 where the power amplifier stage 1002 has been expanded to show more explicitly the driver stage 1002A and the output stage 1002B. In a first exemplary aspect, a detection and alignment circuit 1102A may be positioned at the input 1004. In a second exemplary aspect, a detection and alignment circuit 1102B may be positioned at a node 1104 between the driver stage 1002A and the output stage 1002B. In a third exemplary aspect, a detection and alignment circuit 1102C may be positioned at the output 1006.

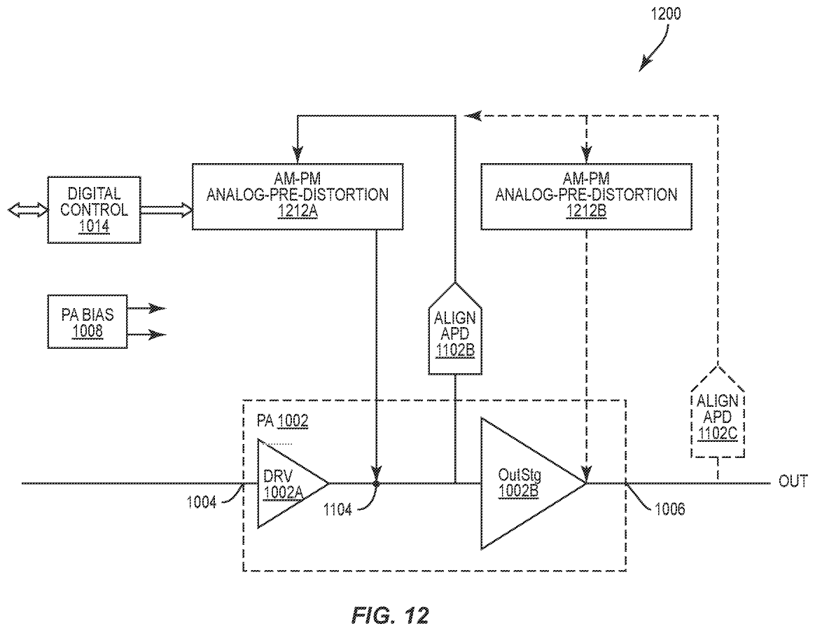

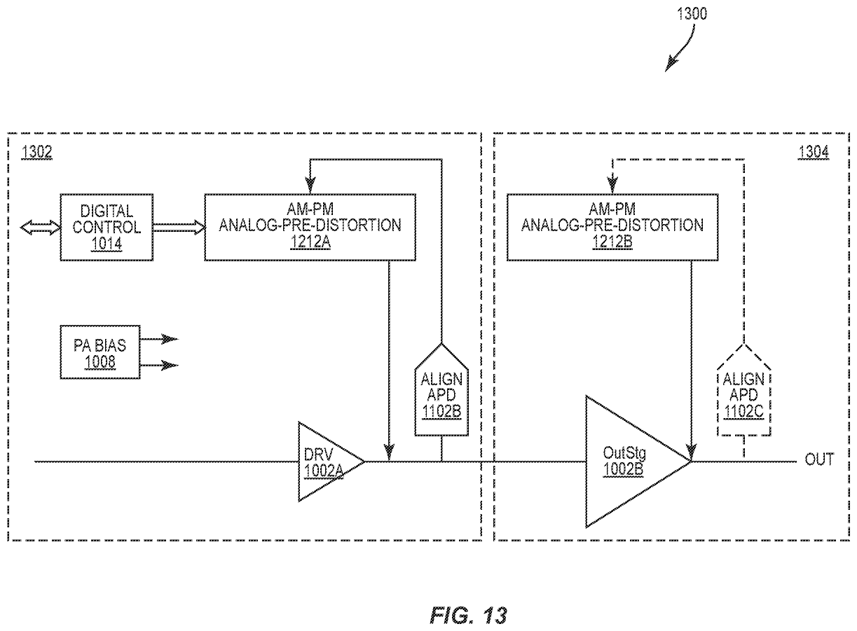

While any of the three positions (1004, 1006, 1104) noted may be used, and in some cases, multiple positions may be used concurrently (as explained below with reference to, for example, FIG. 12 or 13), it is expected that the position at the node 1104 will perform better than the other aspects. Positioning the detection and alignment circuit 1102A at the input 1004 may result in too little swing in the power to provide enough differentiation on which to make correction decisions. In contrast, positioning the detection and alignment circuit 1102C at the output 1006 may have too much power present, which results in excessive power consumption in the AM-PM predistortion circuit 1012. Accordingly, positioning the detection and alignment circuit 1102B at the node 1104 may have some advantages over the other two locations.

In addition to placement of the detection and alignment circuit 1102A, 1102B, 1102C at various positions, injection of the correction signal may occur at the input 1004 or at the node 1104. While it is conceptually possible to correct at the output 1006 (as suggested, for example, in FIG. 10), such correction is likely to consume excess power and be less efficient than at the input 1004 or the node 1104.

As noted above, it is possible that there may be multiple sensing positions, possibly working in conjunction with multiple predistortion circuits. For example, a transmission chain 1200, illustrated in FIG. 12, may include a first AM-PM predistortion circuit 1212A working with a detection and alignment circuit 1102B at the node 1104. A second detection and alignment circuit 1102C at the output 1006 may provide additional information to the first AM-PM predistortion circuit 1212A and/or provide the additional information to an optional second AM-PM predistortion circuit 1212B. The second AM-PM predistortion circuit 1212B may inject the correction signal at the output 1006. In this arrangement, coarse adjustments may be made by the first AM-PM predistortion circuit 1212A and fine adjustments made by the second AM-PM predistortion circuit 1212B. While not shown in FIG. 12, the detection and alignment circuit 1102A may be associated with a third AM-PM predistortion circuit and inject a correction signal at the input 1004. In any case where there are multiple correction signals being injected, there may be communication between the AM-PM predistortion circuits so that the correction signals do not fight each other.

FIG. 13 illustrates a transmission chain 1300 which is provided to show that exemplary aspects of the present disclosure may work in hybrid systems where part of the transmission chain is digital and part of the transmission chain is analog. Specifically, a first portion 1302 of the transmission chain 1300 may be implemented in a complementary metal oxide semiconductor (CMOS) (bulk or silicon on insulator) die while a second portion 1304 of the transmission chain 1300 may be implemented in a gallium arsenide (GaAs) die. In an exemplary aspect, the driver stage 1002A, the bias circuit 1008, the digital controller 1014, the detection and alignment circuit 1102B, and the first AM-PM predistortion circuit 1212A are provided in the first portion 1302, while the output stage 1002B is in the second portion 1304. Optionally, a second detection and alignment circuit 1102C and a second AM-PM predistortion circuit 1212B may be present in the second portion 1304. Note that there is no digital control for the second AM-PM predistortion circuit 1212B in this implementation. Note further that the lack of a digital controller for the second AM-PM predistortion circuit 1212B makes it harder to control and correspondingly more difficult to deploy and as such, it is possible that the detection and alignment circuit 1102C and the second AM-PM predistortion circuit 1212B may be omitted.

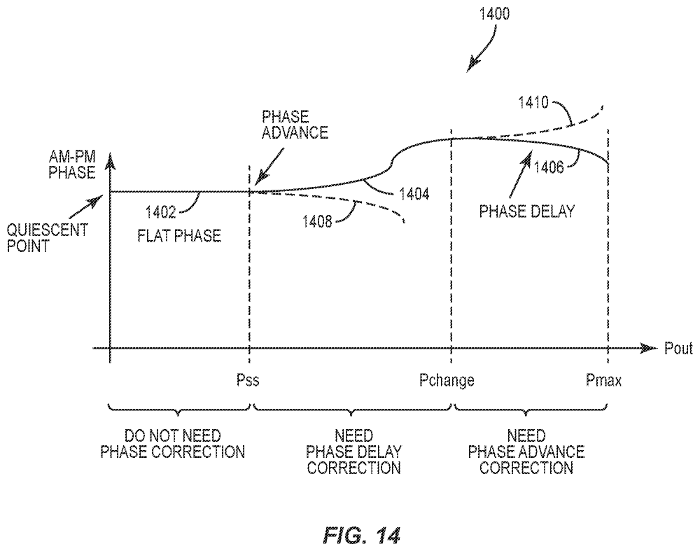

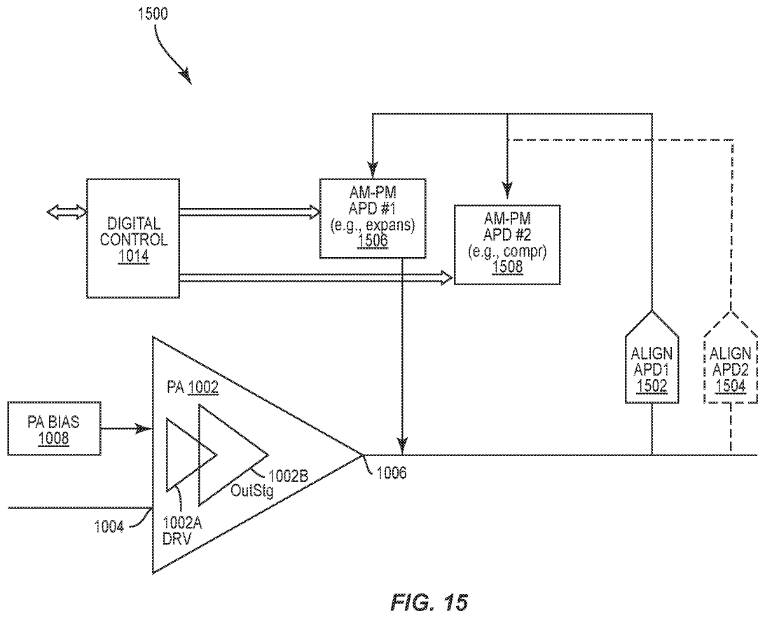

While FIG. 9 contemplates a single sort of inflection in the phase, the real world is not necessarily so neat and there may instances where, as power changes, the phase distortion may change from a phase advance to a phase delay or vice versa. The former possibility is illustrated in FIG. 14. Specifically, a graph 1400 shows with a line segment 1402 how a phase may be linear below power Pss, but between power Pss and power Pchange, a phase advance is present as shown by line segment 1404. Finally, above power Pchange, a phase delay may be present as shown by line segment 1406. The corresponding required predistortions are shown by line segments 1408 and 1410. Providing compensation in such instances where compensation is needed in both advance and delay directions may be done with two predistortion circuits as better illustrated in FIG. 15.

In this regard, FIG. 15 shows a transmission chain 1500 with a first detection and alignment circuit 1502 and a second detection and alignment circuit 1504. The first detection and alignment circuit 1502 is coupled to a first AM-PM predistortion circuit 1506, and the second detection and alignment circuit 1504 is coupled to a second AM-PM predistortion circuit 1508. While FIG. 15 shows the detection and alignment circuits 1502, 1504 positioned at the output 1006, it should be appreciated that they may be positioned at the input 1004, between the stages of the power amplifier stage 1002, or at the output 1006.

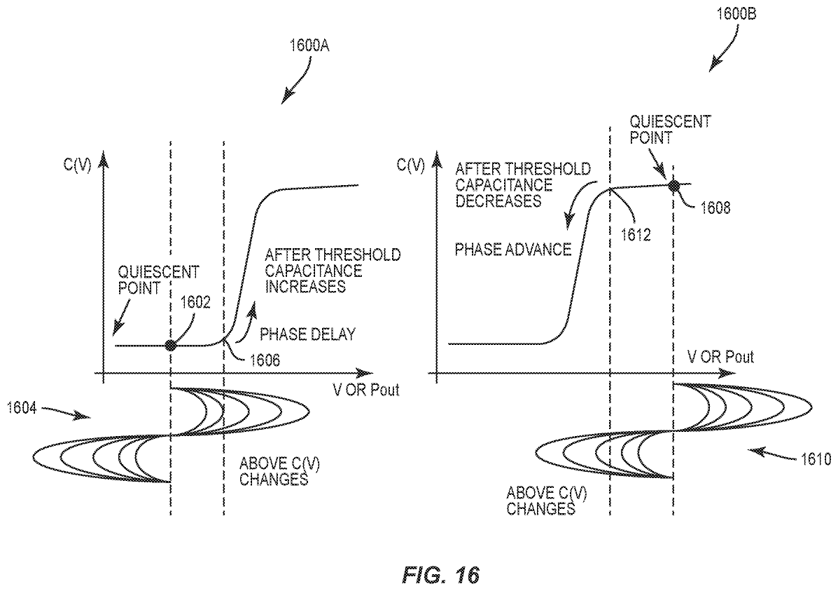

While a variety of options exist to implement any of the AM-PM predistortion circuits of the present disclosure, a device having a non-linear capacitance that varies as a function of voltage provides a ready solution. Further, the device may have a nonlinear variation with a flat portion and a monotonic increase (or a monotonic decrease) in capacitance. A varactor is one such device. FIG. 16 shows graphs 1600A and 1600B of the capacitance as a function of voltage.

In particular, graph 1600A shows a varactor having a first quiescent point 1602 at a relatively low capacitance. As the voltage changes around the quiescent point 1602 (shown generally at 1604), the capacitance will remain flat or, if a threshold 1606 is exceeded, capacitance increases, which allows a phase delay correction signal to be generated.

In contrast, as shown in graph 1600B, the varactor may have a relatively high quiescent point 1608. As the voltage changes around the quiescent point 1608 (shown generally at 1610), the capacitance will remain flat or, if a threshold 1612 is passed, capacitance decreases, which allows a phase advance correction signal to be generated. The quiescent point may be set by the digital controller 1014.

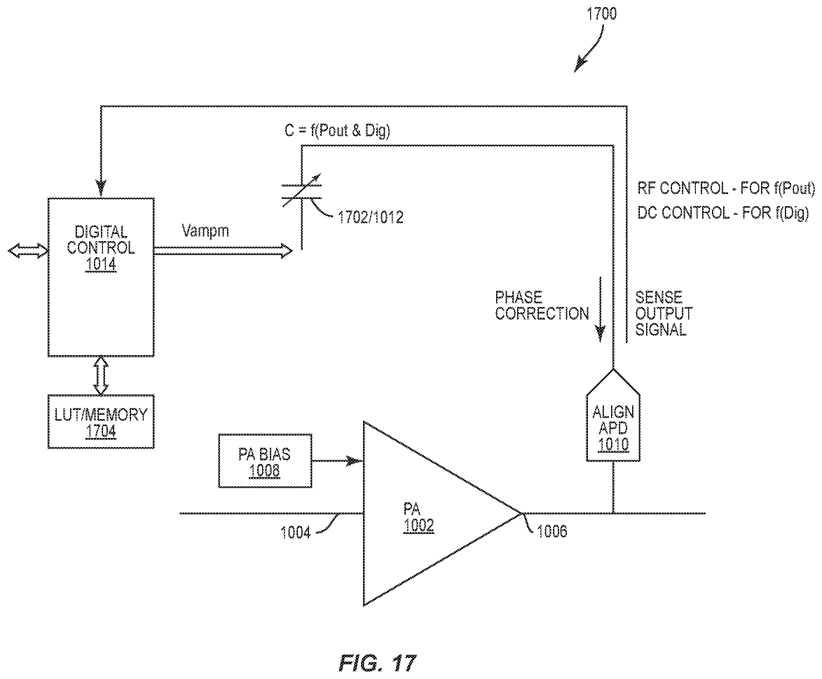

FIG. 17 shows a transmission chain 1700 having a varactor 1702 being used as an AM-PM predistortion circuit 1012. The detection and alignment circuit 1010 reports a sensed output signal to the digital controller 1014, which may use a look-up table (LUT) stored in memory 1704 to determine a voltage signal (Vampm) to send to the varactor 1702 so that a phase correction signal may be provided to the power amplifier stage 1002. While FIG. 17 shows the detection and alignment circuit 1010 positioned at the output 1006, it should be appreciated that it may be positioned at the input 1004, between the stages of the power amplifier stage 1002, or at the output 1006.

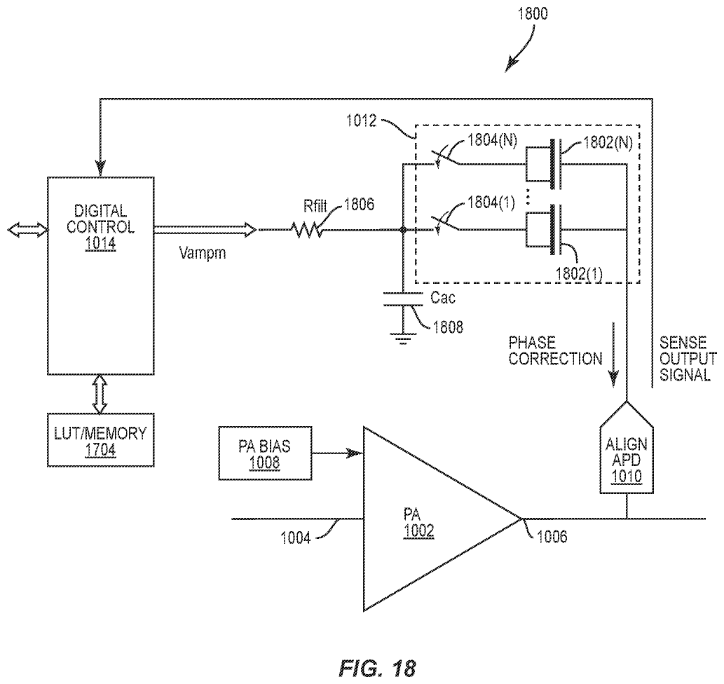

One way to implement a varactor is through an NFET. Further, it should be appreciated that multiple varactors may be used and switched on or off depending on a mode of operation. For example, changing between 4G and 5G may dictate a change in varactor size. Likewise, changing between a power level, frequency, or other parameter may be optimized by changing varactors. A simplified switching system using NFET varactors is illustrated in FIG. 18.

In this regard, FIG. 18 shows a transmission chain 1800 that has a plurality of varactors 1802(1)-1802(N) operating as the AM-PM predistortion circuit 1012. Each varactor 1802(1)-1802(N) may have an associated switch 1804(1)-1804(N) that allows the digital controller 1014 to turn on and off a given varactor 1802(1)-1802(N). Alternatively, some varactors 1802(1)-1802(N) may always be active. Additional control over the varactors 1802(1)-1802(N) may be provided by a filter resistor 1806 and a capacitor 1808. Selective use of varactors in this fashion allows different varactors to provide phase delays and others to provide phase advancements. Combining the varactors 1802(1)-1802(N) in various combinations may allow the precise phase adjustment to be selected. The digital controller 1014 may consult the LUT in the memory 1704 relative to the signal from the detection and alignment circuit 1010 and select appropriate commands to open and close the switches 1804(1)-1804(N) as needed to meet the desired adjustment. While FIG. 18 shows the detection and alignment circuit 1010 positioned at the output 1006, it should be appreciated that it may be positioned at the input 1004, between the stages of the power amplifier stage 1002, or at the output 1006.

Instead of using switches 1804(1)-1804(N), the varactors 1802(1)-1802(N) may be individually controlled as better seen in FIG. 19. In this regard, FIG. 19 shows a transmission chain 1900 that has independent varactors 1802(1)-1802(N). Each varactor 1802(1)-1802(N) has an associated filter resistor 1806(1)-1806(N) and capacitor 1808(1)-1808(N). The digital controller 1014 may generate individual control signals (Vampm1-VampmN). If the control signal is low, the varactor 1802(1)-1802(N) does not turn on, and does not contribute to the correction signal. Selective use of varactors in this fashion allows different varactors to provide phase delays and others to provide phase advancements. Combining the varactors in various combinations may allow the precise phase adjustment to be selected. The digital controller 1014 may consult the LUT in the memory 1704 relative to the signal from the detection and alignment circuit 1010 and select appropriate commands to activate or deactivate different varactors 1802(1)-1802 (N) as needed to meet the desired adjustment. While FIG. 19 shows the detection and alignment circuit 1010 positioned at the output 1006, it should be appreciated that it may be positioned at the input 1004, between the stages of the power amplifier stage 1002, or at the output 1006.

The digital controller 1014 may use not just the signal from the detection and alignment circuit 1010, but may also consider other parameters such as Vcc, frequency, power mode, temperature, cellular mode (e.g., 4G vs. 5G), or the like.

Note also that a given varactor in any of the above aspects may be turned off by moving the quiescent point so that changes in the voltage do not trigger the thresholds 1606, 1612.

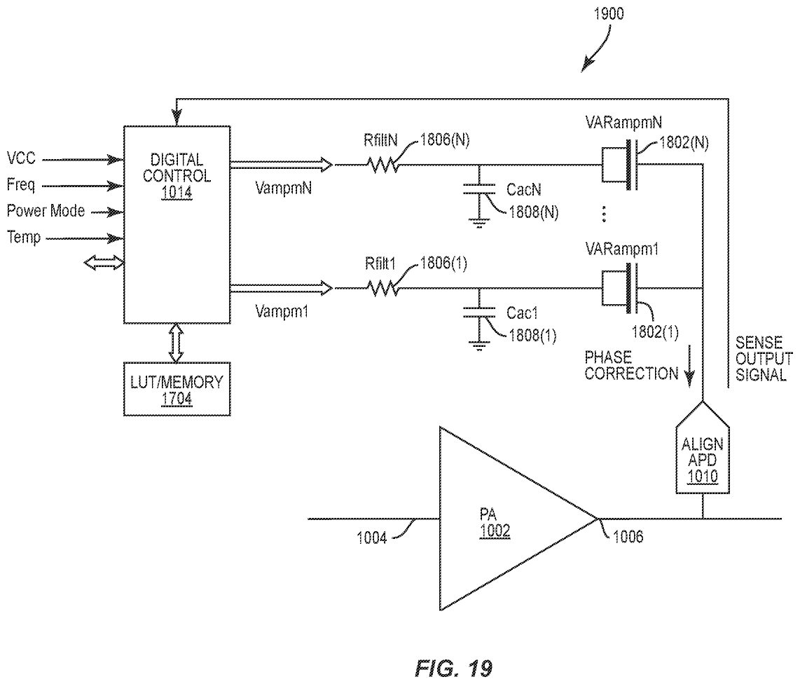

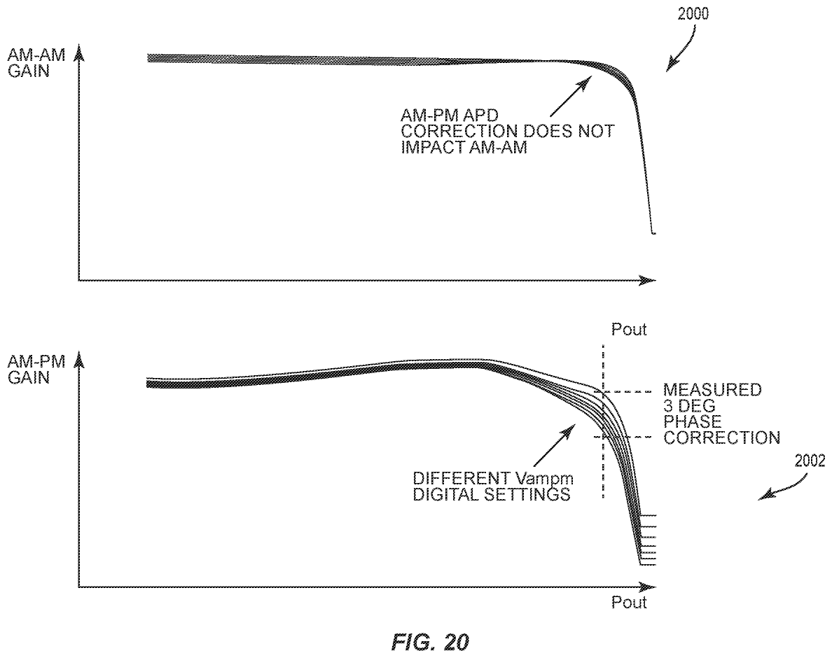

It should further be appreciated that AM-PM correction according to exemplary aspects of the present disclosure does not necessarily affect other parameters or metrics of the power amplifier stage 1002. Thus, as shown in FIG. 20, a first graph 2000 shows that AM-PM predistortion does not affect AM-AM attributes while a second graph 2002 shows how the same AM-PM predistortion affects the output phase. Such orthogonality will be relevant in any AM-AM predistortion schemes.

In addition to the phase predistortion issues, there may be instances where there is amplitude distortion. Again, historical solutions may provide predistortion solutions in the BBP. Such solutions may be impractical or expensive in emerging technologies. Accordingly, exemplary aspects of the present disclosure contemplate providing an open-loop feed-forward APD AM-AM technique to provide amplitude linearization. Many of the concepts of the AM-AM techniques are similar to those used in the AM-PM techniques.

In this regard, FIG. 21 illustrates a transmission chain 2100 that has a power amplifier stage 1002 with an input 1004 and an output 1006. The transmission chain 2100 includes a power sensing circuit, which may be a detection and alignment circuit 2102. The detection and alignment circuit 2102 is in the transmission chain 2100 at the output 1006 and communicates information about a sensed power level to an AM-AM predistortion circuit 2104. The AM-AM predistortion circuit 2104 may be coupled to a digital controller 1014 and a bias circuit 1008. Signals from the AM-AM predistortion circuit 2104 may cause the bias circuit 1008 to adjust a bias signal provided to the power amplifier stage 1002.

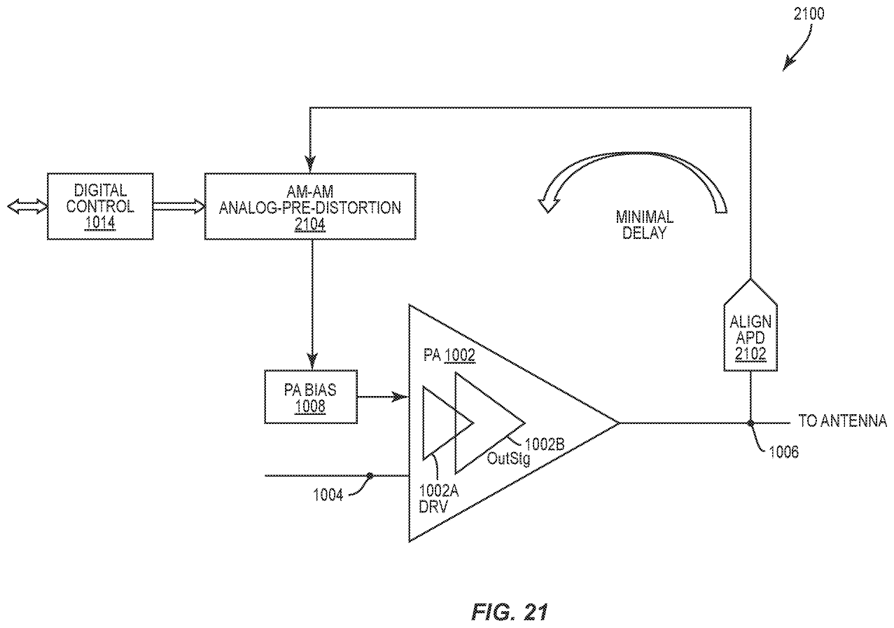

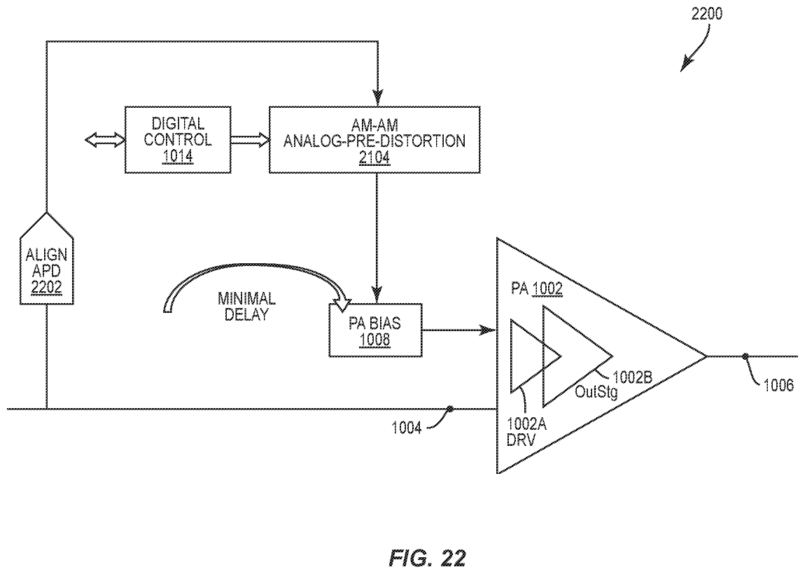

Instead of positioning the detection and alignment circuit at the output 1006, the detection and alignment circuit may be positioned at the input 1004 as better illustrated in FIG. 22, where a transmission chain 2200 includes a detection and alignment circuit 2202 that performs the measurement at the input 1004.

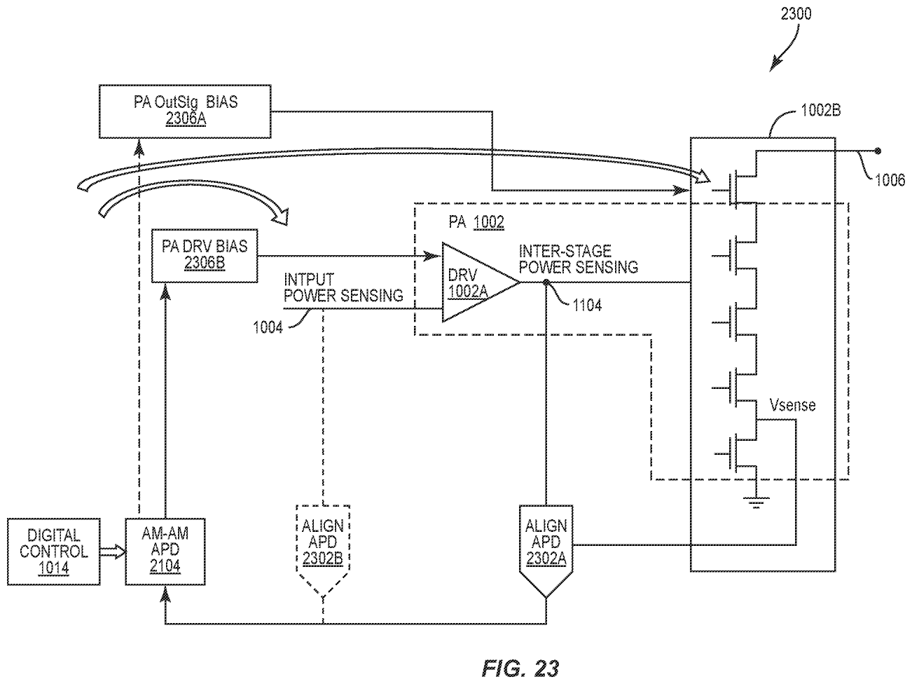

Still further, there may be instances where the detection and alignment circuit may be positioned at the node 1104 and/or there may be multiple detection and alignment circuits as better seen in transmission chain 2300 of FIG. 23. The transmission chain 2300 may have a first detection and alignment circuit 2302A at the node 1104 and an optional second detection and alignment circuit 2302B at the input 1004. The detection and alignment circuits 2302A, 2302B may send information about sensed power to a single AM-AM predistortion circuit 2104 (as illustrated), or there may be multiple respective predistortion circuits (not shown). The predistortion circuit(s) 2104 may control multiple bias circuits 2306A, 2306B so as to control the distortion applied at each stage 1002A, 1002B independently.

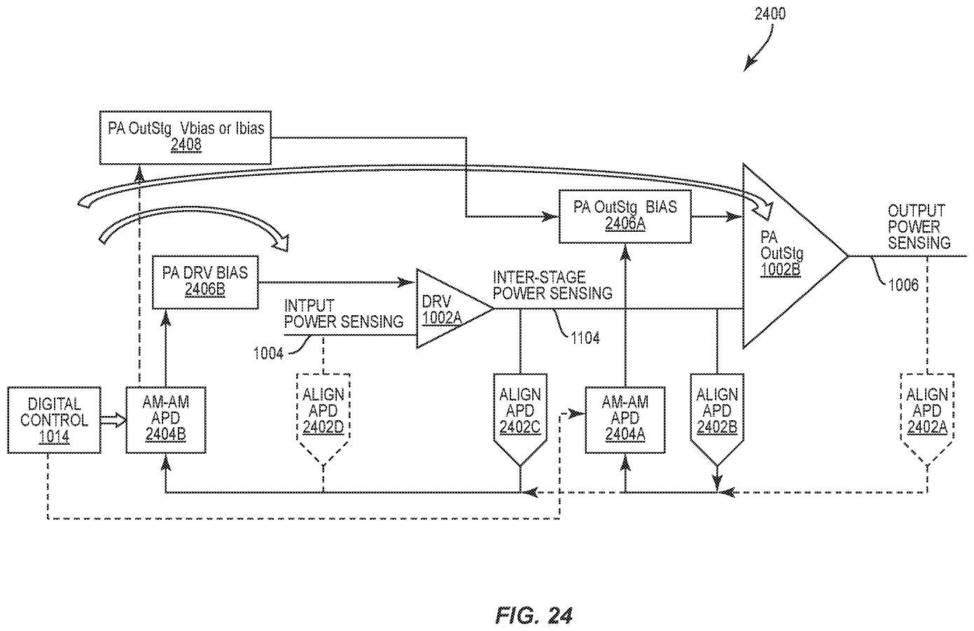

FIG. 24 provides a block diagram of a transmission chain 2400 having a variety of open-loop feed-forward loops to provide AM-AM predistortion according to exemplary aspects of the present disclosure. In particular, the transmission chain 2400 may have a first detection and alignment circuit 2402A at the output 1006. The first detection and alignment circuit 2402A may be associated with a first predistortion circuit 2404A. A second detection and alignment circuit 2402B may also be associated with the first predistortion circuit 2404A. The first predistortion circuit 2404A may control an output stage bias circuit 2406A.

A third detection and alignment circuit 2402C may be associated with a second predistortion circuit 2404B and take measurements at the node 1104. A fourth detection and alignment circuit 2402D may also be associated with the second predistortion circuit 2404B and take measurements at the input 1004. The second predistortion circuit 2404B may control a driver stage bias circuit 2406B and/or also provide input to the output stage bias circuit 2406A through an intermediate bias circuit 2408. The digital controller 1014 may communicate with both predistortion circuits 2404A and 2404B to coordinate predistortion signals so that the two predistortion circuits 2404A and 2404B do not cause overcorrection and conflicting instructions.

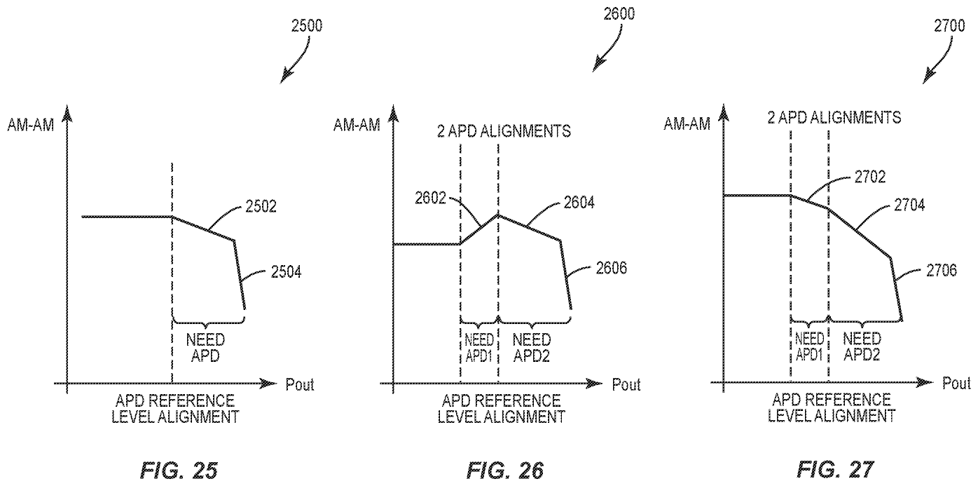

It should be appreciated that much like phase distortion may have phase delays and phase advancements for which predistortion is used to compensate, so too may there be a variety of amplitude distortions as better illustrated in FIGS. 25-27. For example, in FIG. 25, a graph 2500 of power versus AM distortion shows that there may be a first amplitude compression 2502 having a first slope followed by a harder amplitude compression 2504 having a harder or more severe slope. The first amplitude compression 2502 may be overcome with predistortion while the severe slope of the harder amplitude compression 2504 may exceed the ability of a predistortion to compensate.

Similarly, FIG. 26 shows a graph 2600 having the same axes, but a first segment is an amplitude expansion 2602 having a first slope and a second segment is an amplitude compression 2604 having a second slope. Finally, a third segment is a hard compression 2606. Different predistortion circuits may be used to provide different sorts of compensation or correction signals to the bias circuits.

Likewise, FIG. 27 shows a graph 2700 having the same axes, but with two relatively soft compressions. That is, a first segment 2702 has a first slope for which compensation may be applied. A second segment 2704 has a second slope for which compensation may also be applied. However, a third segment 2706 has a hard compression that exceeds compensation capabilities.

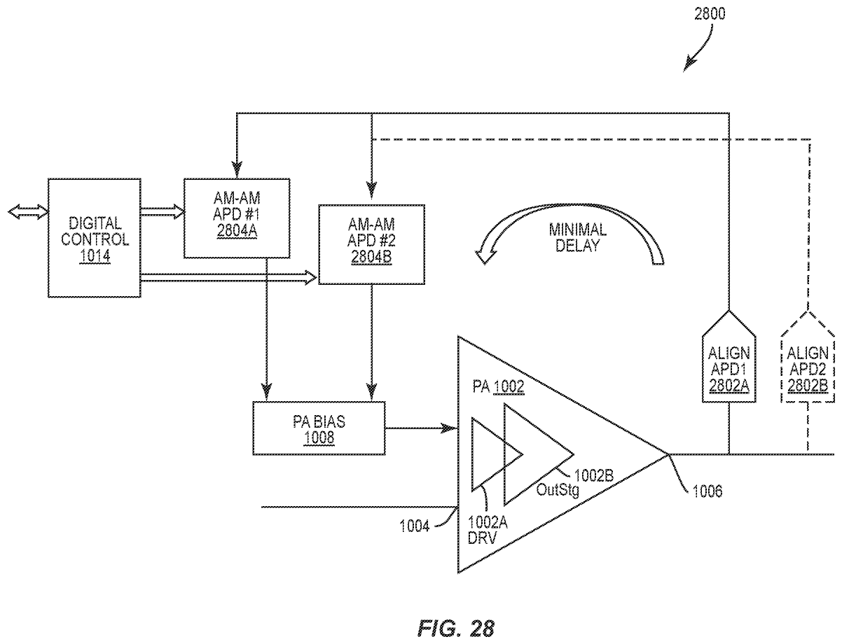

To provide the different compensation signals to the bias circuits, a transmission chain may use multiple loops such that one loop works to correct amplitude compression and another loop works to correct amplitude expansion. In this regard, FIG. 28 illustrates a transmission chain 2800 having a first detection and alignment circuit 2802A that works with a first predistortion circuit 2804A to form a first loop and provide a correction signal to a bias circuit 1008. In an exemplary aspect, this first loop may provide correction to compressed amplitudes. A second detection and alignment circuit 2802B works with a second predistortion circuit 2804B to form a second loop and provide a second correction signal to the bias circuit 1008. The digital controller 1014 may interoperate with the predistortion circuits 2804A, 2804B to make sure they do not conflict. While shown as being positioned at the output 1006, it should be appreciated that other positions for the detection and alignment circuits 2802A, 2802B may be provided.

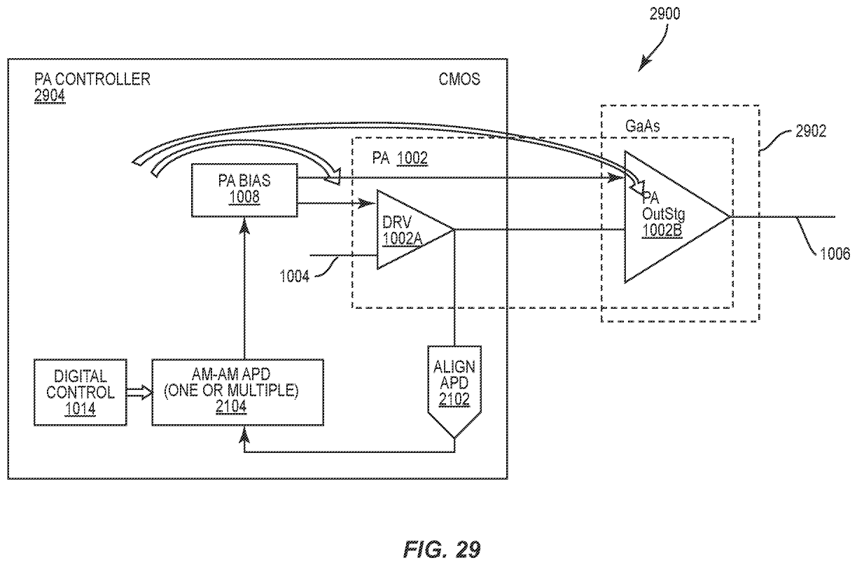

As with the phase distortion circuitry, it is possible to have portions of the open-loop feed-forward amplitude predistortion loop be provided in different dice. Specifically, as illustrated in FIG. 29, a transmission chain 2900 may have a first die 2902. The output stage 1002B of the power amplifier stage 1002 may be implemented in the first die 2902 and the first die 2902 may be a GaAs die. Additionally, the transmission chain 2900 may have a second die 2904. The second die 2904 may include the bias circuit 1008, the driver stage 1002A, the digital controller 1014, the detection and alignment circuit 2102, and the predistortion circuit 2104. The second die 2904 may be a CMOS die. The bias circuit 1008 may have separate circuitry for the driver stage 1002A and the output stage 1002B, but both may be present in the second die 2904.

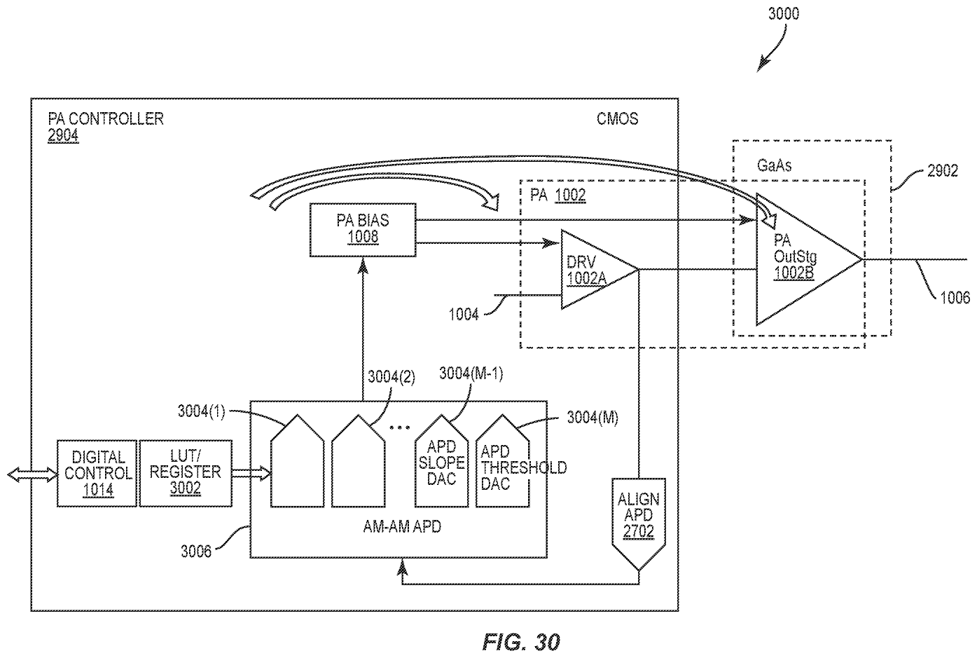

The predistortion circuit may be implemented to control only the bias of a single gain stage (e.g., the driver stage 1002A or the output stage 1002B) or the predistortion circuit may control all stages. In this regard, FIG. 30 illustrates a transmission chain 3000 which may be a two-die architecture like the transmission chain 2900 of FIG. 29. In the transmission chain 3000, the digital controller 1014 may work with a LUT 3002 that is stored in a register or other memory device. Based on values in the LUT 3002, the digital controller 1014 may set values for one or more DACs 3004(1)-3004(M) in a predistortion circuit 3006. The values stored in the DACs 3004(1)-3004(M) may be slope and/or threshold values corresponding to the inflection points such as those shown in FIGS. 25-27 and the slopes of the various line segments. These values may be used to set bias currents or bias voltages produced by the bias circuit 1008 or the like.

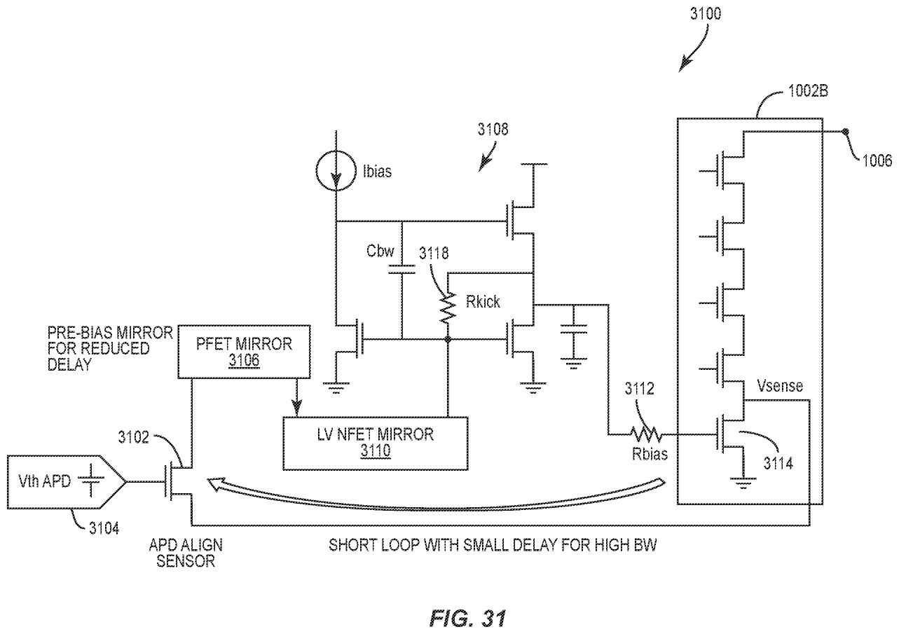

Additional details about an exemplary bias circuit are provided with reference to FIG. 31. In this regard, FIG. 31 shows a transmission chain 3100 where a detection and alignment circuit 3102 is a FET that activates based on a threshold voltage 3104. A P-type FET (PFET) current mirror 3106 works with a Wilson current mirror 3108 and an NFET current mirror 3110 to provide a bias signal through a bias resistor 3112 to a bottom stage 3114 of a cascode stack within the output stage 1002B.

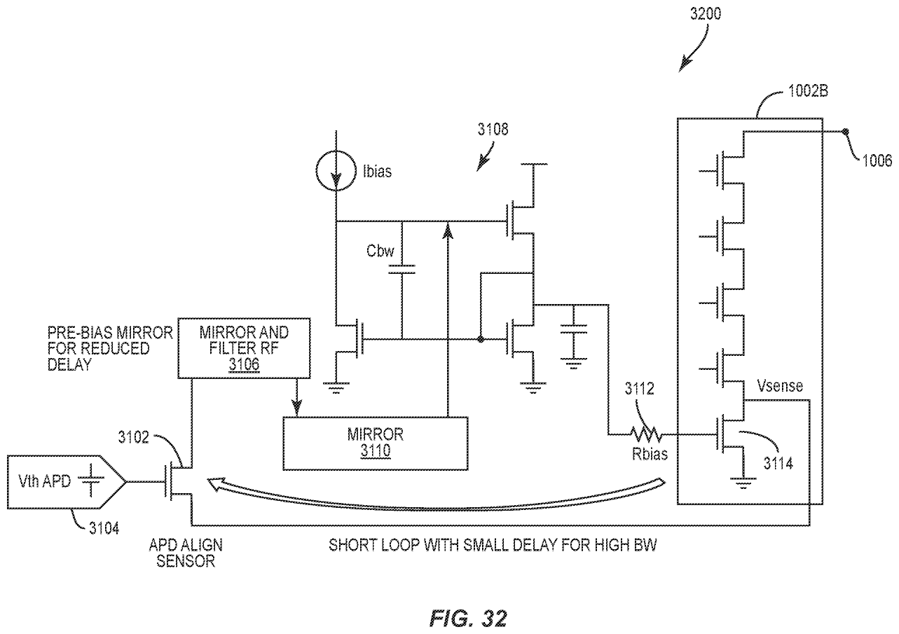

A kicker resistor 3118 may introduce noise and thus may be eliminated as shown in a transmission chain 3200 of FIG. 32. Removal of the kicker resistor 3118 causes the NFET mirror 3110 to couple to the Wilson current mirror 3108 at a different point, but otherwise, the transmission chain 3200 is substantially similar to the transmission chain 3100 of FIG. 31.

Many of the circuits described above rely on a bias circuit. In some instances, the bias circuit may be distinct, but in other instances, the bias circuit may be incorporated into a digital controller. Because there may be tension between the demands of the AM-PM and AM-AM predistortion and the protection circuits, the bias circuit may need to control the predistortion while in an over voltage or over current condition. Still further, the bias circuit may need to select between different power sources that have different power levels. Thus, the bias circuit may include circuitry that allows the circuitry to float between power levels so that the transition does not introduce unwanted fluctuations. Still further, the bias circuit may provide bias signals to multiple stacked transistors in the power amplifier in such a manner so as to avoid collapsing any of the transistors. One such approach is a piecewise linear bias signal. Additional details are provided with reference to FIGS. 33-44.

In this regard FIG. 33 illustrates a bias circuit 3300 which may be used in any of the previously discussed aspects (e.g., bias circuits 204, 304, 504, 606, 1008, 2306A, 2306B, 2406A, 2406B and any bias circuits incorporated into a digital controller). The bias circuit 3300 may receive power from two power sources 3302 (Vbat) and 3304 (Vcc), which may be at different power levels. A switching circuit 3306 may allow selection between the two power sources 3302, 3304. The power source 3304 may also provide power to a buck-boost DC-DC converter 3308, which provides power to a power amplifier 3310 through an inductor 3312. The power amplifier 3310 may be similar to other power amplifiers described herein and includes a plurality of stacked FETs 3314(1)-3314(N), where, as illustrated, N is 5, with a primary FET 3314(1) and cascode FETs 3314(2)-3314(5). The bias circuit 3300 may include a float circuit 3316 which assists in transitioning between different voltage levels when the switching circuit 3306 switches between power sources 3302, 3304.

The bias circuit 3300 may switch between power sources based on fluctuations in relative voltage levels in the power sources 3302, 3304. In general, the bias circuit 3300 will choose the higher of the two power sources 3302, 3304 as generally shown by graph 3400 in FIG. 34. In an exemplary aspect, the first power source 3302 may vary between approximately 2.0 and 4.6 volts (V) while the second power source 3304 may vary between 0.5 and 5.0 V. The bias circuit 3300 will generally need between 2.0 and 5.0 V. Accordingly, in region 3402, the bias circuit 3300 will use the first power source 3302 and in region 3404, the bias circuit 3300 will use the second power source 3304.

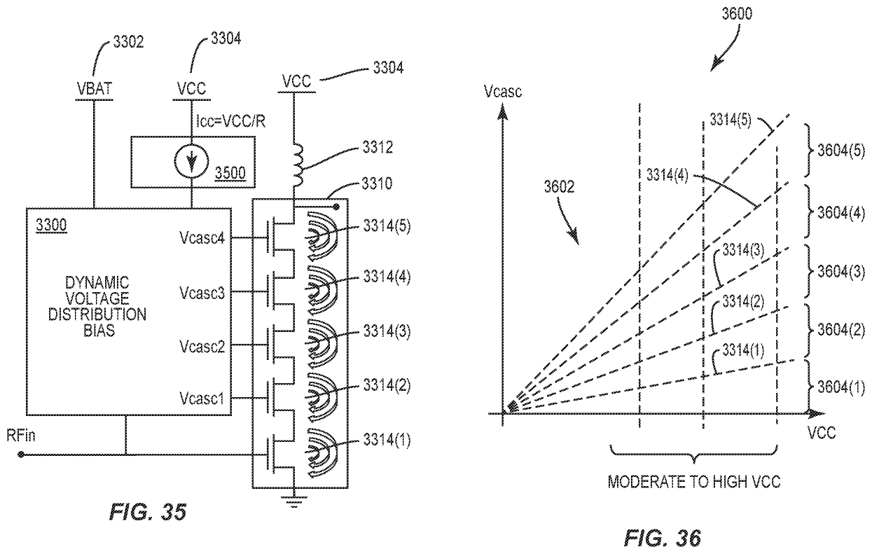

In an exemplary aspect, the bias circuit 3300 may provide equal bias signals to each of the FETs 3314(1)-3314(5) as generally seen in FIG. 35. To assist in providing equal bias signals, the power source 3304 may be converted to a current source 3500 that provides Icc=Vcc/R where R is some resistance in the current source 3500.

As shown in graph 3600 of FIG. 36, if equal bias signals are supplied, there is a risk that at low power levels, the stacked FETs 3314(1)-3314(5) may turn off in region 3602. At higher power source levels, the voltage drops 3604(1)-3604(5) may all be equal and large enough to keep the FETs 3314(1)-3314(5) active.

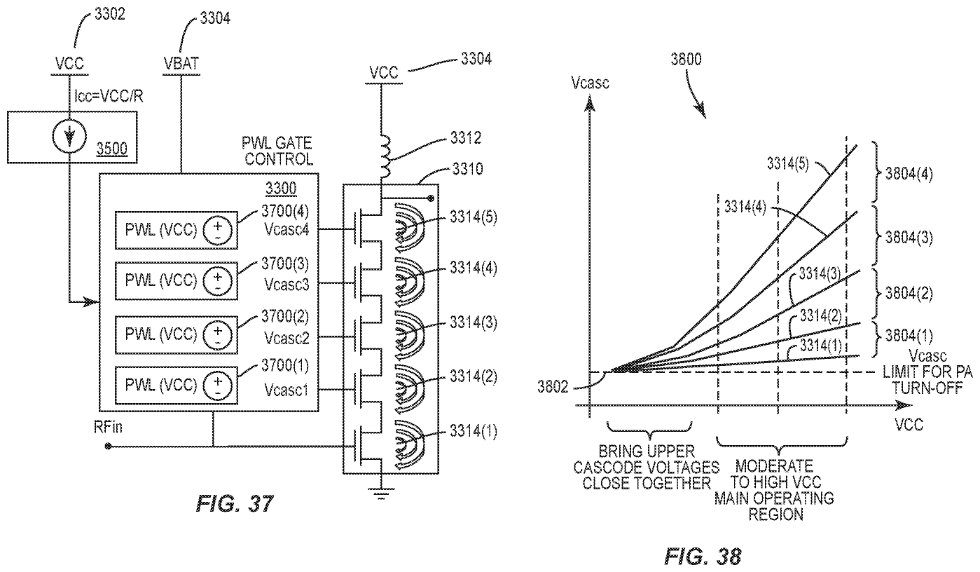

Alternatively and more effectively, the bias signals provided to the FETs 3314(1)-3314(5) may be a piecewise linear (PWL) function of the input voltage as shown in FIG. 37. Specifically, the bias circuit 3300 may include circuitry 3700(1)-3700(4) that acts to create piecewise linear functions of the input voltage for the bias signals. The end result of this circuitry may look something like graph 3800 in FIG. 38, where there is an initial floor 3802, below which the bias signal for any given FET 3314(1)-3314(5) does not fall. The floor 3802 may be chosen such that the FETs 3314(1)-3314(5) may operate in triode mode, and as the power level increases, the slopes of the respective bias signals may change in piecewise fashion until the spacing 3804(1)-3804(4) is generally uniform (although there is no strict requirement that the spacing be equal). In the graph 3800, the slopes may change multiple times for each FET 3314(1)-3314(5) if needed or desired.

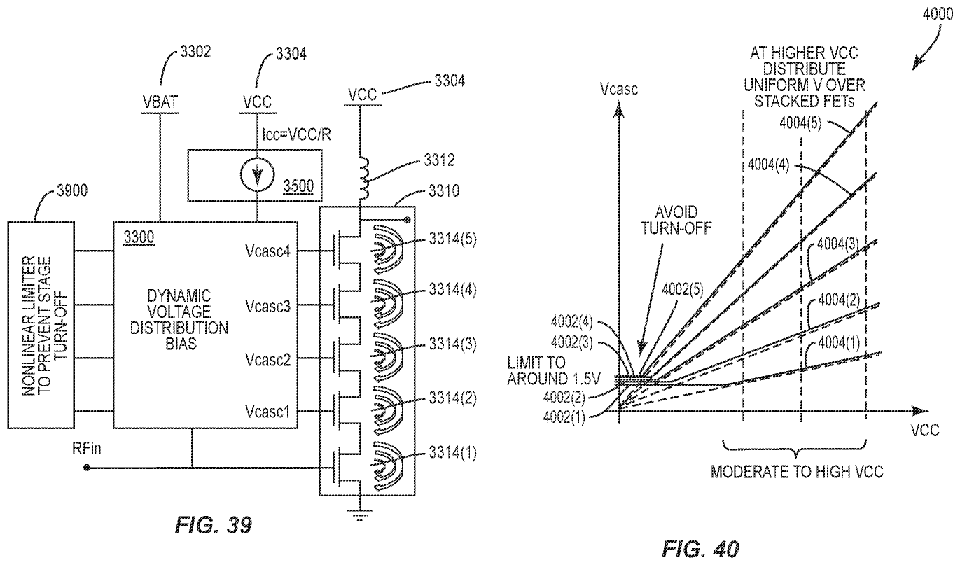

Another option would be to have a generally flat portion and a single slope to the bias signals. Such a result may be effectuated by a nonlinear limiter circuit 3900 shown in FIG. 39, which provides a floor voltage for the bias signals of the bias circuit 3300. This may result in the piecewise linear functions shown by graph 4000 of FIG. 40. Flat portions 4002(1)-4002(5) reflect operation in triode mode to avoid turn off for the FETs 3314(1)-3314(5), followed by slopes 4004(1)-4004(5) to have uniform spacing between the FETs 3314(1)-3314(5) at higher voltages. It should be appreciated that the limiter circuit 3900 may be used with other piecewise linear functions such as those shown in FIG. 37.

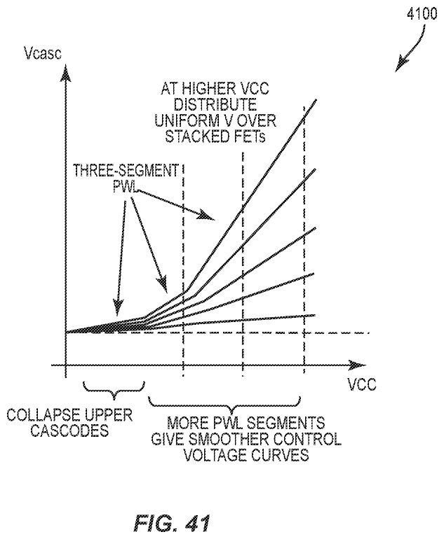

FIG. 41 provides still another piecewise linear function for the bias signals in graph 4100.

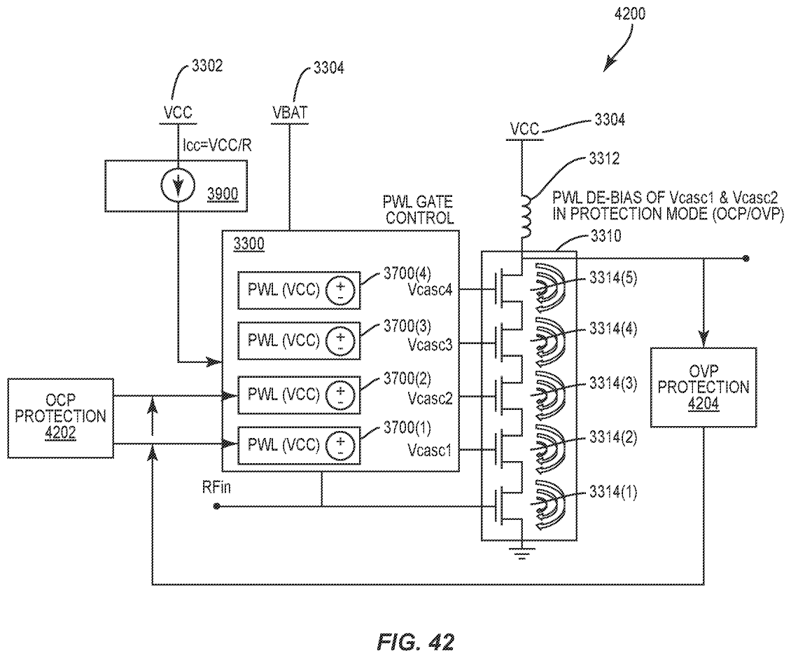

It should be appreciated that the protection circuits described above will actively try to debias the FETs 3314(1)-3314(5) when over power conditions occur. In contrast, the linearization circuits are likely to be demanding that the bias signals be increased to offset phase delays or amplitude compression. It is more important to protect the power amplifier from damage that may be caused by over power conditions, and accordingly, the bias circuit 3300 of the present disclosure may receive information from the over voltage and over current protection circuitry as illustrated in FIG. 42. Specifically, the bias circuit 3300 in circuit 4200 receives a signal from an over current protection circuit 4202 and an over voltage protection circuit 4204. Note that the debiasing caused by the over current protection circuit 4202 may debias two of the FETs 3314(1)-3314(5) (e.g., FETs 3314(2) and 3314(3)) to avoid stressing the second stacked cascode FET.

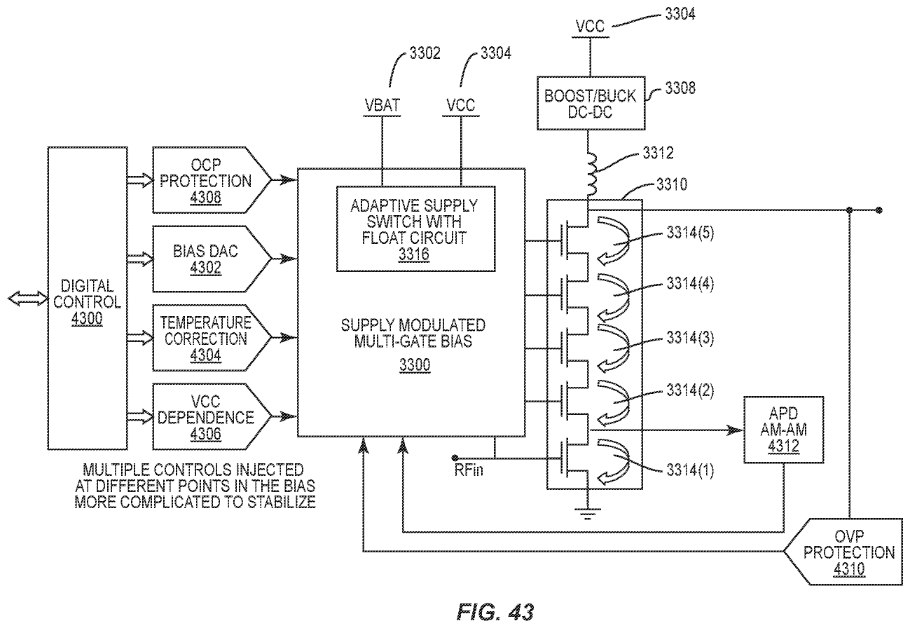

To facilitate balancing the competing demands, the bias circuit 3300 may interoperate with a digital controller 4300 as illustrated in FIG. 43. The digital controller 4300 may be the same as the digital controller 1014 described above. The digital controller 4300 may provide a bias DAC control signal 4302, a temperature correction signal 4304, and a source dependence signal 4306 to the bias circuit 3300. The bias circuit 3300 may also receive a signal 4308 from the over current protection circuit 4202 and a signal 4310 from the over voltage protection circuit 4204. Additionally, a signal from linearization circuitry 4312 may be provided to the bias circuit 3300. The linearization circuitry 4312 may be the AM-AM predistortion circuitry and/or the AM-PM predistortion circuitry. As illustrated, these signals may be received separately and distinctly from one another. When the bias circuit 3300 receives an over power condition signal (e.g., the signal 4308 or 4310), the bias circuit 3300 may open a switch (not shown) to disconnect the input from the linearization circuitry 4312 so that the signal from the linearization circuitry 4312 does not conflict with the debiasing required to protect the power amplifier.

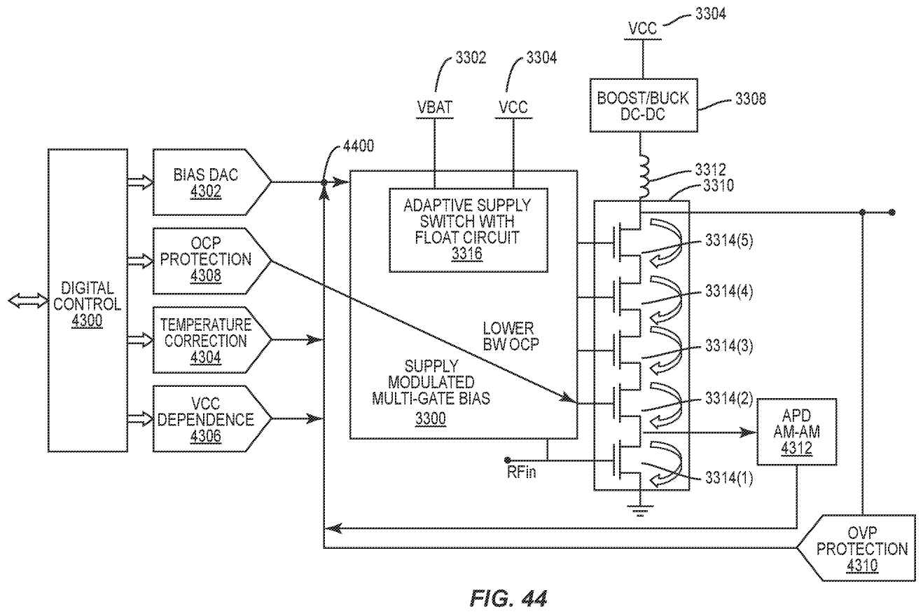

Instead of multiple inputs for the bias circuit 3300, a single injection point 4400 illustrated in FIG. 44 may be provided. This may assist in maintaining stability and/or provide a wider bandwidth. Further, the signal 4308 from the over current protection circuit 4202 may be provided directly to the bias signal for the FET 3314(2) to expedite debiasing the FET 3314(2).

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A transmission chain comprising:
a power amplifier stage comprising a signal input, a voltage supply input, and at least one bias input distinct and different from the voltage supply input; and
a bias circuit coupled to the power amplifier stage, the bias circuit comprising:
a bias signal output coupled to the at least one bias input of the power amplifier stage and configured to provide at least one bias signal to the power amplifier stage;
a first power supply input configured to be coupled to a first power supply that provides a first voltage level;
a second power supply input configured to be coupled to a second power supply that provides a second voltage level;
a switching circuit selectively switching between the first power supply input and the second power supply input; and
a float circuit configured to smooth a transition between the first voltage level and the second voltage level when the switching circuit switches between the first power supply input and the second power supply input.

2. The transmission chain of claim 1, wherein the power amplifier stage comprises a plurality of field-effect transistors (FETs) and the bias circuit further is coupled to each of the plurality of FETs at a respective gate.

3. The transmission chain of claim 1, wherein the switching circuit is configured to switch between the first power supply input and the second power supply input based on fluctuations in relative difference between the first voltage level and the second voltage level.

4. The transmission chain of claim 1, further comprising a current source coupled to the first power supply input.

5. The transmission chain of claim 2, wherein the bias circuit is configured to provide equal bias signals to each of the plurality of FETs.

6. The transmission chain of claim 2, wherein the bias circuit is configured to provide bias signals that are piecewise linear functions of an input voltage.

7. The transmission chain of claim 6, wherein the piecewise linear functions are configured to avoid FET turn off at low input voltages.

8. The transmission chain of claim 1, wherein the bias circuit is further configured to receive information from a temperature sensor.

9. The transmission chain of claim 1, wherein the bias circuit is further configured to receive information from an over current protection circuit.

10. The transmission chain of claim 1, wherein the bias circuit is further configured to receive information from an over voltage protection circuit.

11. The transmission chain of claim 10, wherein the bias circuit is configured to prioritize information from the over voltage protection circuit over information relating to the first power supply and the second power supply.

12. The transmission chain of claim 1, wherein the bias circuit further comprises:
an over power protection signal input configured to receive a signal that causes the bias circuit to debias the power amplifier stage; and
a predistortion signal input configured to cause the bias circuit to apply a predistortion bias to the power amplifier stage; and
wherein the bias circuit is configured to disable the predistortion bias when the signal indicates an over power condition is occurring.

13. The transmission chain of claim 12, wherein the power amplifier stage comprises a plurality of field-effect transistors (FETs) and the bias circuit is coupled to respective gates of each of the plurality of FETs.

14. The transmission chain of claim 13, wherein the bias circuit is configured to switch between the first power supply input and the second power supply input based on fluctuations in a relative difference between the first voltage level and the second voltage level.

15. The transmission chain of claim 14, further comprising a current source coupled to the first power supply input.

16. The transmission chain of claim 13, wherein the bias circuit is configured to provide equal bias signals to each of the plurality of FETs.

17. The transmission chain of claim 13, wherein the bias circuit is configured to provide bias signals that are piecewise linear functions of an input voltage.

18. The transmission chain of claim 17, wherein the piecewise linear functions are configured to avoid FET turn off at low input voltages.
